(19) United States
(12) Patent Application Publication
(10) Pub. No.: US 2026/0331065 A1
(43) Pub. Date: Oct. 22, 2026

(54) SHIFT REGISTER, DISPLAY PANEL, AND DISPLAY DEVICE

(71) Applicant: Xiamen Tianma Display Technology Co., Ltd., Xiamen (CN)

(72) Inventors: Xuehuan FENG, Xiamen (CN); Yana GAO, Xiamen (CN); Xingyao ZHOU, Xiamen (CN); Zhiqiang XIA, Xiamen (CN); Kang YANG, Xiamen (CN)

(73) Assignee: Xiamen Tianma Display Technology Co., Ltd., Xiamen (CN)

(21) Appl. No.: 19/704,860

(22) Filed: Jun. 11, 2026

(30) Foreign Application Priority Data
Dec. 31, 2025 (CN) 202512058431.4

(51) Int. Cl. G09G 3/3266; G11C 19/28

(52) U.S. Cl. CPC G09G 3/3266; G11C 19/28; G09G 2300/0819; G09G 2300/0842; G09G 2310/0286

(57) ABSTRACT

Provided are a shift register, a display panel, and a display device. The shift register includes a control unit, an output unit, and a node voltage regulation unit. The control unit is configured to receive an input signal and a first clock signal, and to control the potential of a first node and the potential of a second node. The output unit includes a first output sub-unit and a second output sub-unit. A second terminal of the first output sub-unit and a second terminal of the second output sub-unit are connected and output an output signal. A control terminal of the first output sub-unit is connected to the first node. A control terminal of the second output sub-unit is connected to the second node.

### CROSS-REFERENCE TO RELATED APPLICATION

This application claims priority to Chinese Patent Application No. 202512058431.4 filed Dec. 31, 2025, the disclosure of which is incorporated herein by reference in its entirety.

### TECHNICAL FIELD

Embodiments of the present disclosure relate to the field of display technology, and in particular, to a shift register, a display panel, and a display device.

### BACKGROUND

With the continuous development of display technology, an increasing number of electronic devices with display functions have been widely applied in people's daily life and work, bringing significant convenience to users.

In the field of display, particularly in organic light-emitting diode (OLED) display technology, oxide is widely applied in medium and large-sized display panels due to good uniformity of the oxide. However, display products employing oxide processes currently face issues of unstable output from shift register circuits. Specifically, when the threshold voltage of the oxide thin film transistor (oxide TFT) in the shift register circuit shifts toward a negative value, the pull-up node fails to maintain its potential due to leakage current. This leads to output instability, renders the output signal susceptible to interference, and ultimately compromises the display quality of the display panel.

### SUMMARY

Embodiments of the present disclosure provide a shift register, a display panel, and a display device. The potential of a first node is stabilized to ensure that an output signal can maintain the output of an active-level signal of a first output sub-unit, thereby improving output stability of the shift register and enhancing display quality of the display panel.

In a first aspect, embodiments of the present disclosure provide a shift register. The shift register includes a control unit, an output unit, and a node voltage regulation unit.

The control unit is configured to receive an input signal and a first clock signal, and to control the potential of a first node and the potential of a second node. One of the potential of the first node and the potential of the second node is a logic high-level signal, and the other of the potential of the first node and the potential of the second node is a logic low-level signal.

The output unit includes a first output sub-unit and a second output sub-unit. A first terminal of the first output sub-unit receives a first voltage signal, and a first terminal of the second output sub-unit receives a second voltage signal. A second terminal of the first output sub-unit and a second terminal of the second output sub-unit are connected and output an output signal. One of the first voltage signal and the second voltage signal is a logic high-level signal, and the other of the first voltage signal and the second voltage signal is a logic low-level signal.

A control terminal of the first output sub-unit is connected to the first node, and the first output sub-unit is configured to output the first voltage signal when the potential of the first node is an active-level signal. A control terminal of the second output sub-unit is connected to the second node, and the second output sub-unit is configured to output the second voltage signal when the potential of the second node is an active-level signal.

The node voltage regulation unit is connected to the first node and configured to maintain the potential of the first node at an active-level signal for the first output sub-unit during at least part of a period in which the potential of the second node is an inactive-level signal.

In a second aspect, embodiments of the present disclosure also provide a display panel including a driver circuit. The driver circuit includes N stages of shift registers cascaded in sequence according to any one of the preceding first aspect.

An output signal of an i-th stage shift register is input into a j-th stage shift register as an input signal of the j-th stage shift register, where N≥2, 1≤i≤N, and 1≤j≤N.

In a third aspect, embodiments of the present disclosure also provide a display device including the display panel according to any one of the preceding second aspect.

Embodiments of the present disclosure provide a shift register, a display panel, and a display device. A node voltage regulation unit is disposed at an input side of a first node in the shift register, and the potential of the first node is stabilized so that stable output of an active pulse of an output signal is achieved, thereby improving the output stability of the shift register and ensuring that a rising edge, a falling edge, and a duty cycle of the active pulse of the output signal are always within a preset accuracy range. A stable output signal may also precisely control the switching timing and current magnitude of each transistor in a pixel circuit and avoid problems such as pixel lighting delay and brightness deviation caused by pulse abnormality. The cooperative operation of respective pixel units in the display panel is ensured from the level of the shift register, and clear presentation of display images and stable display of the display panel are achieved. This ensures that the display panel may exhibit a clear, smooth, and stable image effect under various display modes, thereby meeting application requirements for high-quality display. All thin film transistors in the shift register may be oxide thin film transistors, which may also reduce image sticking and lower manufacturing cost.

### BRIEF DESCRIPTION OF DRAWINGS

FIG. 1A is a schematic diagram illustrating the structure of a shift register in the related art.

FIG. 1B is a drive timing graph of the shift register shown in FIG. 1A.

FIG. 2 is a schematic diagram illustrating the structure of a display panel according to an embodiment of the present disclosure.

FIG. 3 is a schematic diagram illustrating the structure of a driver circuit of the display panel shown in FIG. 2.

FIG. 4 is a schematic diagram illustrating the overall structure of a shift register in the driver circuit shown in FIG. 3.

FIG. 5 is a schematic diagram illustrating one specific structure of the shift register in the driver circuit shown in FIG. 4.

FIG. 6 is a drive timing diagram of each stage of shift register in the driver circuit shown in FIG. 5.

FIG. 7 is a schematic diagram illustrating another specific structure of the shift register in the driver circuit shown in FIG. 4.

FIG. 8 is a drive timing diagram of each stage of shift register in the driver circuit shown in FIG. 7.

FIG. 9 is a schematic diagram illustrating another specific structure of the shift register in the driver circuit shown in FIG. 4.

FIG. 10 is a drive timing diagram of each stage of shift register in the driver circuit shown in FIG. 9.

FIG. 11 is a schematic diagram illustrating another specific structure of the shift register in the driver circuit shown in FIG. 4.

FIG. 12 is a drive timing diagram of each stage of shift register in the driver circuit shown in FIG. 11.

FIG. 13 is a schematic diagram illustrating another specific structure of the shift register in the driver circuit shown in FIG. 4.

FIG. 14 is a schematic diagram illustrating another specific structure of the shift register in the driver circuit shown in FIG. 4.

FIG. 15 is a schematic diagram illustrating another specific structure of the shift register in the driver circuit shown in FIG. 4.

FIG. 16 is a schematic diagram illustrating another specific structure of the shift register in the driver circuit shown in FIG. 4.

FIG. 17 is a schematic diagram illustrating another specific structure of the shift register in the driver circuit shown in FIG. 4.

FIG. 18 is a schematic diagram illustrating another specific structure of the shift register in the driver circuit shown in FIG. 4.

FIG. 19 is a schematic diagram illustrating another specific structure of the shift register in the driver circuit shown in FIG. 4.

FIG. 20 is a schematic diagram illustrating another specific structure of the shift register in the driver circuit shown in FIG. 4.

FIG. 21 is a schematic diagram illustrating another specific structure of the shift register in the driver circuit shown in FIG. 4.

FIG. 22 is a schematic diagram illustrating another specific structure of the shift register in the driver circuit shown in FIG. 4.

FIG. 23 is a schematic diagram illustrating a structure of a pixel circuit in the display panel shown in FIG. 2.

FIG. 24 is a diagram illustrating the structure of a display device according to an embodiment of the present disclosure.

### DETAILED DESCRIPTION

The solutions in the embodiments of the present disclosure are described clearly and completely in conjunction with drawings in the embodiments of the present disclosure from which the solutions are better understood by those skilled in the art. Apparently, the embodiments described below are part, not all, of the embodiments of the present disclosure. Based on the embodiments described herein, all other embodiments acquired by those of ordinary skill in the art on the premise that no creative work is done are within the scope of the present disclosure.

It is to be noted that terms such as “first” and “second” in the description, claims, and drawings of the present disclosure are used to distinguish between similar objects and are not necessarily used to describe a particular order or sequence. It is to be understood that the data used in this manner are interchangeable where appropriate so that the embodiments of the present disclosure described herein may also be implemented in a sequence not illustrated or described herein. Additionally, terms “comprising”, “including”, and any other variations thereof are intended to encompass a non-exclusive inclusion. For example, a process, method, system, product, or device that includes a series of steps or units not only includes the expressly listed steps or units but may also include other steps or units that are not expressly listed or are inherent to such a process, method, product, or device.

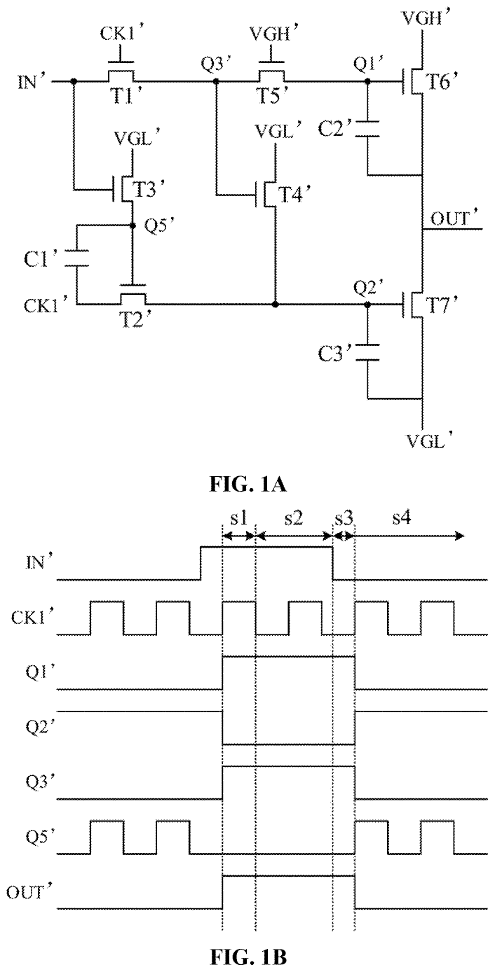

FIG. 1A is a schematic diagram illustrating the structure of a shift register in the related art. FIG. 1B is a drive timing graph of the shift register shown in FIG. 1A. As shown in FIG. 1A and FIG. 1B, the shift register has a 7T3C structure (T represents a transistor, and C represents a capacitor), and transistors in the shift register may all be N-channel transistors. A first terminal of a first transistor T1′ receives an input signal IN′, a second terminal of the first transistor T1′ is connected to a third node Q3′, and a control terminal of the first transistor T1′ receives a first clock signal CK1′. A first terminal of a second transistor T2′ receives the first clock signal CK1′, a second terminal of the second transistor T2′ is connected to a second node Q2′, and a control terminal of the second transistor T2′ is connected to a fifth node Q5′. A first terminal of a third transistor T3′ receives a logic low-level signal VGL′, a second terminal of the third transistor T3′ is connected to the fifth node Q5′, and a control terminal of the third transistor T3′ receives the input signal IN′. A first terminal of a fourth transistor T4′ receives the logic low-level signal VGL′, a second terminal of the fourth transistor T4′ is connected to the second node Q2′, and a control terminal of the fourth transistor T4′ is connected to the third node Q3′. A first terminal of a fifth transistor T5′ is connected to the second node Q2′, a second terminal of the fifth transistor T5′ is connected to a first node Q1′, and a control terminal of the fifth transistor T5′ receives a logic high-level signal VGH′. A first terminal of a sixth transistor T6′ receives the logic high-level signal VGH′, a second terminal of the sixth transistor T6′ outputs an output signal OUT′, and a control terminal of the sixth transistor T6′ is connected to the first node Q1′. A first terminal of a seventh transistor T7′ receives the logic low-level signal VGL′, a second terminal of the seventh transistor T7′ outputs the output signal OUT′, and a control terminal of the seventh transistor T7′ is connected to the second node Q2′. In addition, two terminals of a first capacitor C1′ are connected to the first terminal of the second transistor T2′ and the control terminal of the second transistor T2′, respectively. Two terminals of a second capacitor C2′ are connected to the first terminal of the sixth transistor T6′ and the control terminal of the sixth transistor T6′, respectively. Two terminals of a third capacitor C3′ are connected to the first terminal of the seventh transistor T7′ and the control terminal of the seventh transistor T7′, respectively.

The timing control process corresponding to the shift register shown in FIG. 1A may specifically refer to FIG. 1B. In an s1 phase, the first clock signal CK1′ is at a logic high level. In this case, the first transistor T1′ is turned on, a logic high level corresponding to the input signal IN′ may be transmitted to the third node Q3′, and the fifth transistor T5′ is constantly turned on. Therefore, potentials of the third node Q3′ and the first node Q1′ are both at a logic high level. In this case, the sixth transistor T6′ is turned on, and a logic high-level signal VGH′ corresponding to the first terminal of the sixth transistor T6′ may be transmitted to the second terminal of the sixth transistor T6′, that is, the output signal OUT′ output by the shift register is correspondingly at a logic high level. In addition, the input signal IN′ is at a logic high level. In this case, the third transistor T3′ is turned on, and a logic low-level signal VGL′ corresponding to the first terminal of the third transistor T3′ may be transmitted to the fifth node Q5′. In this case, the second transistor T2′ is turned off. In addition, the potential of the third node Q3′ is at a logic high level. In this case, the fourth transistor T4′ is turned on, and the logic low-level signal VGL′ corresponding to the first terminal of the fourth transistor T4′ may be transmitted to the second node Q2′. In this case, the seventh transistor T7′ is turned off.

In an s2 phase, when the first clock signal CK1′ is at a logic low level, the first transistor T1′ is turned off, and the logic high level corresponding to the input signal IN′ cannot be transmitted to the third node Q3′. At the same time, the second capacitor C2′ stabilizes a voltage to the potential of the previous phase so that the potential of the first node Q1′ is still maintained at a logic high level. In this case, the sixth transistor T6′ continues to be turned on, and the logic high-level signal VGH′ corresponding to the first terminal of the sixth transistor T6′ may be transmitted to the second terminal of the sixth transistor T6′, that is, the output signal OUT′ output by the shift register is correspondingly at a logic high level. In addition, the input signal IN′ is at a logic high level. In this case, the third transistor T3′ is turned on, and a logic low-level signal VGL′ corresponding to the first terminal of the third transistor T3′ may be transmitted to the fifth node Q5′. In this case, the second transistor T2′ is turned off. In addition, the fifth transistor T5′ is constantly turned on, and the potentials of the third node Q3′ and the first node Q1′ are both maintained at a logic high level. In this case, the fourth transistor T4′ is turned on, and the logic low-level signal VGL′ corresponding to the first terminal of the fourth transistor T4′ may be transmitted to the second node Q2′. In this case, the seventh transistor T7′ is turned off. In the s2 phase, when the first clock signal CK1′ is at a logic high level, the first transistor T1′ is turned on, the logic high level corresponding to the input signal IN′ may be transmitted to the third node Q3′, and the fifth transistor T5′ is constantly turned on. Therefore, the potentials of the third node Q3′ and the first node Q1′ are both at a logic high level. In this case, the sixth transistor T6′ is turned on, and the logic high-level signal VGH′ corresponding to the first terminal of the sixth transistor T6′ may be transmitted to the second terminal of the sixth transistor T6′, that is, the output signal OUT′ output by the shift register is correspondingly at a logic high level.

In an s3 phase, the first clock signal CK1′ is at a logic low level. In this case, the first transistor T1′ is turned off, and the logic high level corresponding to the input signal IN′ cannot be transmitted to the third node Q3′. At the same time, the second capacitor C2′ stabilizes the voltage to the potential of the previous phase so that the potential of the first node Q1′ is still maintained at a logic high level. In this case, the sixth transistor T6′ continues to be turned on, and the logic high-level signal VGH′ corresponding to the first terminal of the sixth transistor T6′ may be transmitted to the second terminal of the sixth transistor T6′, that is, the output signal OUT′ output by the shift register is correspondingly at a logic high level. In addition, the input signal IN′ is at a logic low level. In this case, the third transistor T3′ is turned off, and the logic low-level signal VGL′ corresponding to the first terminal of the third transistor T3′ cannot be transmitted to the fifth node Q5′. In this case, the second transistor T2′ is turned off. In addition, the fifth transistor T5′ is constantly turned on, and the potentials of the third node Q3′ and the first node Q1′ are both maintained at a logic high level. In this case, the fourth transistor T4′ is turned on, and the logic low-level signal VGL′ corresponding to the first terminal of the fourth transistor T4′ may be transmitted to the second node Q2′. At the same time, the third capacitor C3′ stabilizes the voltage to the potential of the previous phase so that the potential of the second node Q2′ is still maintained at a logic low level. In this case, the seventh transistor T7′ is turned off.

In an s4 phase, when the first clock signal CK1′ is at a logic high level, the first transistor T1′ is turned on, and a logic low level corresponding to the input signal IN′ may be transmitted to the third node Q3′. The fifth transistor T5′ is constantly turned on so that the potentials of the third node Q3′ and the first node Q1′ are both at a logic low level. In this case, the sixth transistor T6′ is turned off. In addition, the input signal IN′ is at a logic low level. In this case, the third transistor T3′ is turned off, and the logic low-level signal VGL′ corresponding to the first terminal of the third transistor T3′ cannot be transmitted to the fifth node Q5′. However, at this time, the first capacitor C1′ stabilizes the voltage to the potential of the previous phase, that is, the potential of the first clock signal CK1′. Therefore, the potential of the fifth node Q5′ is at a logic high level corresponding to the first clock signal CK1′. In this case, the second transistor T2′ is turned on. The logic high level corresponding to the first clock signal CK1′ may be transmitted to the second node Q2′. In this case, the seventh transistor T7′ is turned on, and the logic low-level signal VGL′ corresponding to the first terminal of the seventh transistor T7′ may be transmitted to the second terminal of the seventh transistor T7′, that is, the output signal OUT′ output by the shift register is correspondingly at a logic low level. In the s4 phase, when the first clock signal CK1′ is at a logic low level, the first transistor T1′ is turned off, and the logic low level corresponding to the input signal IN′ cannot be transmitted to the third node Q3′. At the same time, the second capacitor C2′ stabilizes the voltage to the potential of the previous phase so that the potential of the first node Q1′ is still maintained at a logic low level. In this case, the sixth transistor T6′ continues to be turned off. In addition, the input signal IN′ is at a logic low level. In this case, the third transistor T3′ is turned off, and the logic low-level signal VGL′ corresponding to the first terminal of the third transistor T3′ cannot be transmitted to the fifth node Q5′. However, at this time, the first capacitor C1′ stabilizes the voltage to the potential of the previous phase, that is, the potential of the first clock signal CK1′. Therefore, the potential of the fifth node Q5′ is a logic low level corresponding to the first clock signal CK1′. In this case, the second transistor T2′ is turned off. Moreover, at this time, the third capacitor C3′ stabilizes the voltage to the potential of the previous phase so that the potential of the second node Q2′ is still maintained at a logic high level. In this case, the seventh transistor T7′ continues to be turned on, and the logic low-level signal VGL′ corresponding to the first terminal of the seventh transistor T7′ may be transmitted to the second terminal of the seventh transistor T7′, that is, the output signal OUT′ output by the shift register is correspondingly at a logic low level.

The turn-on conditions of N-channel transistors are as follows: Vg>Vs (that is, the gate voltage is greater than the source voltage), and Vgs>Vth (that is, the gate-source voltage is greater than the threshold voltage). For the above shift register including N-channel transistors, in terms of the turn-on conditions of the N-channel transistors, the following problems exist: In the s2 phase, when the threshold voltage Vth of the N-channel transistor shifts toward a negative value, the first transistor T1′ may not be effectively turned off, that is, the first transistor T1′ may be turned on again. At the same time, the fifth transistor T5′ is in an on state. Therefore, the first node Q1′, the fifth transistor T5′, the third node Q3′, and the first transistor T1′ form a leakage path. Such leakage current prevents the high potential of the first node Q1′ from being maintained. When the potential of the first node Q1′ is lower than the corresponding logic high-level signal VGH′, the potential of the sixth transistor T6′ floats, thereby causing unstable signal output at the second terminal of the sixth transistor T6′, that is, the output signal OUT′ of the shift register is susceptible to interference. At the same time, when the threshold voltage Vth of the seventh transistor T7′ shifts toward a negative value, a voltage division occurs between the sixth transistor T6′ and the seventh transistor T7′, which further causes incomplete signal output of the shift register. In a more easily understandable manner, in the s2 phase, the sixth transistor T6′ has weak bootstrapping capability during output, causing the potential of the first node Q1′ to be insufficiently high. The potential of the first node Q1′ may not always be maintained at a logic high level. The potential of the first node Q1′ is easily interfered by leakage current, resulting in the potential of the first node Q1′ being insufficient to ensure stable turn-on of the sixth transistor T6′ and subsequent output of the active-level signal of the output signal OUT′ at the second terminal of the sixth transistor T6′, which further causes abnormal signal output of the shift register.

Based on the above technical problems, embodiments of the present disclosure provide a shift register. The shift register includes a control unit, an output unit, and a node voltage regulation unit. The control unit is configured to receive an input signal and a first clock signal, and to control the potential of a first node and the potential of a second node. One of the potential of the first node and the potential of the second node is a logic high-level signal, and the other of the potential of the first node and the potential of the second node is a logic low-level signal. The output unit includes a first output sub-unit and a second output sub-unit. A first terminal of the first output sub-unit receives a first voltage signal, and a first terminal of the second output sub-unit receives a second voltage signal. A second terminal of the first output sub-unit and a second terminal of the second output sub-unit are connected and output an output signal. One of the first voltage signal and the second voltage signal is a logic high-level signal, and the other of the first voltage signal and the second voltage signal is a logic low-level signal. A control terminal of the first output sub-unit is connected to the first node, and the first output sub-unit is configured to output the first voltage signal when the potential of the first node is an active-level signal. A control terminal of the second output sub-unit is connected to the second node, and the second output sub-unit is configured to output the second voltage signal when the potential of the second node is an active-level signal. The node voltage regulation unit is connected to the first node and configured to maintain the potential of the first node at an active-level signal for the first output sub-unit during at least part of a period in which the potential of the second node is an inactive-level signal.

According to the technical solution in the embodiments of the present disclosure, a node voltage regulation unit is disposed at an input side of a first node in the shift register, and the potential of the first node is stabilized so that stable output of an active pulse of an output signal is achieved, thereby improving the output stability of the shift register and ensuring that a rising edge, a falling edge, and a duty cycle of the active pulse of the output signal are always within a preset accuracy range. A stable output signal may also precisely control the switching timing and current magnitude of each transistor in a pixel circuit and avoid problems such as pixel lighting delay and brightness deviation caused by pulse abnormality. The cooperative operation of respective pixel units in the display panel is ensured from the level of the shift register, and clear presentation of display images and stable display of the display panel are achieved. This ensures that the display panel may exhibit a clear, smooth, and stable image effect under various display modes, thereby meeting application requirements for high-quality display. All thin film transistors in the shift register may be oxide thin film transistors, which may also reduce image sticking and lower manufacturing cost.

The above is the core idea of the present disclosure, and the technical solutions in the embodiments of the present disclosure are described clearly and completely hereinafter in conjunction with the drawings in the embodiments of the present disclosure. Based on the embodiments of the present disclosure, all other embodiments obtained by those of ordinary skill in the art without creative work are within the scope of the present disclosure.

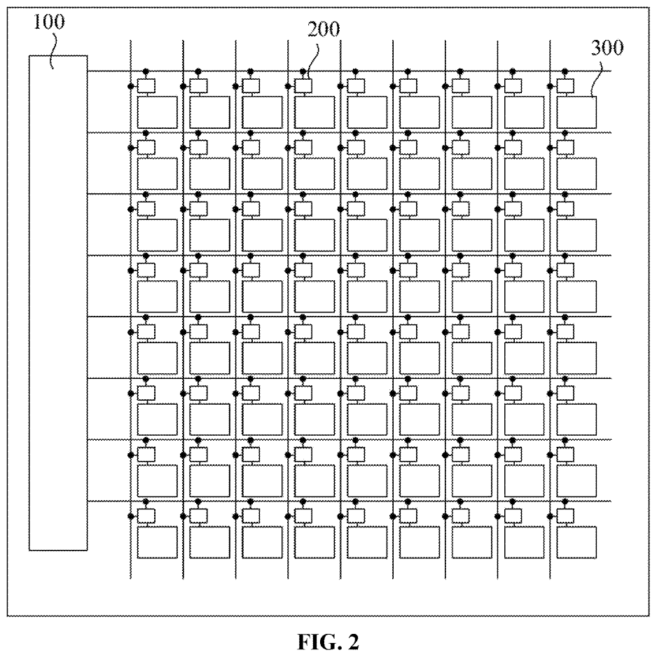

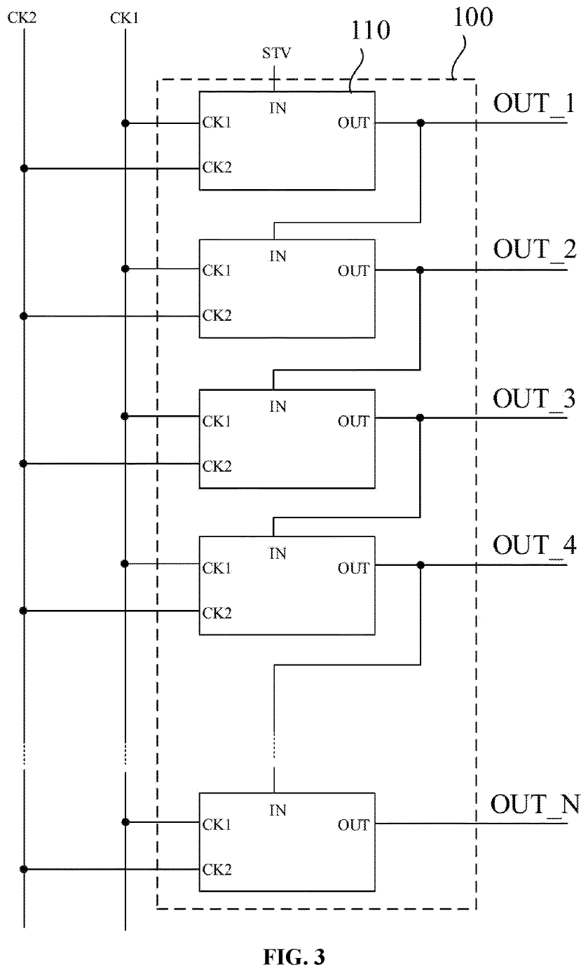

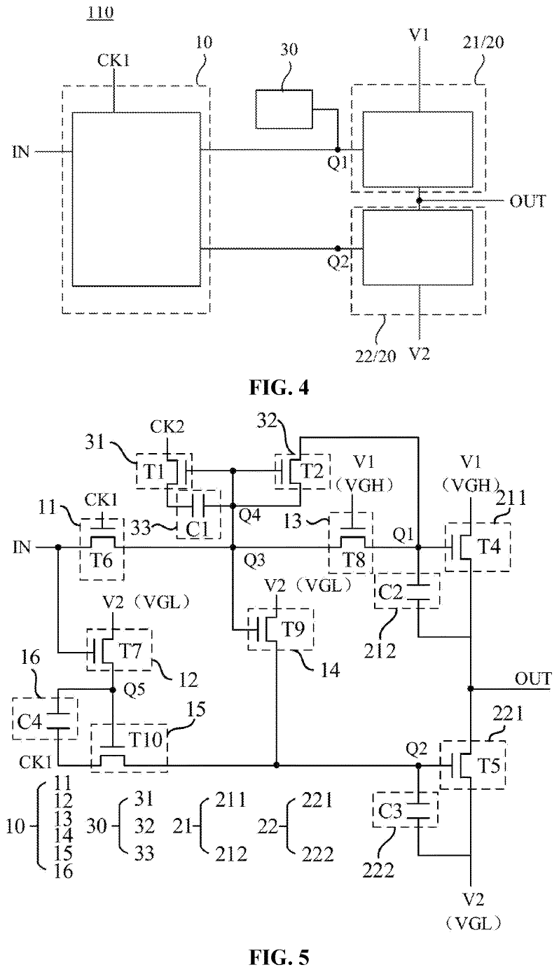

The shift register provided by the embodiments of the present disclosure may be disposed in a display panel. The relationship between the display panel and the shift register is briefly described first as follows: FIG. 2 is a schematic diagram illustrating the structure of a display panel according to an embodiment of the present disclosure. FIG. 3 is a schematic diagram illustrating the structure of a driver circuit of the display panel shown in FIG. 2. FIG. 4 is a schematic diagram illustrating the overall structure of a shift register in the driver circuit shown in FIG. 3. As shown in FIG. 2, FIG. 3, and FIG. 4, the display panel includes a driver circuit 100, and the driver circuit 100 includes N stages of shift registers 110 cascaded in sequence provided by any one of the embodiments of the present disclosure. An output signal OUT of an i-th stage shift register 110 is input into a j-th stage shift register 110 as an input signal IN of the j-th stage shift register 110, where N≥2, 1≤i≤N, and 1≤j≤N.

Specifically, as may be seen from FIG. 2 and FIG. 3, at least two stages of shift registers 110 are disposed in the driver circuit 100 of the display panel, and the at least two stages of shift registers 110 form a cascade. That is, an output signal OUT of a shift register 110 of a certain stage serves as an input signal IN of a shift register 110 of a subsequent stage. Illustratively, FIG. 3 shows that an output signal OUT of a shift register 110 of a previous adjacent stage serves as an input signal IN of a shift register 110 of a next stage. In addition, for any stage of shift register 110, under the control of a first clock signal CK1 and a second clock signal CK2, an output signal OUT may be shifted relative to an input signal IN, and the level transition process of the input signal IN and the output signal OUT may not occur at the same time, thereby achieving an effective delayed shift register effect. Illustratively, an input signal IN of the first stage may also be understood as an STV signal.

With continued reference to FIG. 4, the shift register 110 includes a control unit 10, an output unit 20, and a node voltage regulation unit 30. The control unit 10 is configured to receive an input signal IN and a first clock signal CK1 and to control the potential of a first node Q1 and the potential of a second node Q2, where one of the potential of the first node Q1 and the potential of the second node Q2 is a logic high-level signal VGH, and the other of the potential of the first node Q1 and the potential of the second node Q2 is a logic low-level signal VGL. The output unit 20 includes a first output sub-unit 21 and a second output sub-unit 22. A first terminal of the first output sub-unit 21 receives a first voltage signal V1, and a first terminal of the second output sub-unit 22 receives a second voltage signal V2. A second terminal of the first output sub-unit 21 and a second terminal of the second output sub-unit 22 are connected and output an output signal OUT. One of the first voltage signal V1 and the second voltage signal V2 is a logic high-level signal VGH, and the other of the first voltage signal V1 and the second voltage signal V2 is a logic low-level signal VGL. A control terminal of the first output sub-unit 21 is connected to the first node Q1, and the first output sub-unit 21 is configured to output the first voltage signal V1 when the potential of the first node Q1 is an active-level signal. A control terminal of the second output sub-unit 22 is connected to the second node Q2, and the second output sub-unit 22 is configured to output the second voltage signal V2 when the potential of the second node Q2 is an active-level signal. The node voltage regulation unit 30 is connected to the first node Q1 and is configured to maintain the potential of the first node Q1 at an active-level signal for the first output sub-unit 21 during at least part of a period in which the potential of the second node Q2 is an inactive-level signal.

First, it is to be noted that an active-level signal can be understood as a signal for controlling a corresponding connected sub-unit, unit, circuit, or the like to be turned on, connected, or operated, and an inactive-level signal can be understood as a signal for controlling a corresponding connected sub-unit, unit, circuit, or the like to be turned off, cut off, or not operated. As shown in FIG. 4, an active-level signal corresponding to the potential of the first node Q1 and an active-level signal corresponding to the potential of the second node Q2 may both be illustratively at a logic high level, and an inactive-level signal corresponding to the potential of the first node Q1 and an inactive-level signal corresponding to the potential of the second node Q2 may both be illustratively at a logic low level. In addition, transistors used in the control unit 10, the output unit 20, and the node voltage regulation unit 30 may be thin film transistors, field-effect transistors, or other devices with the same characteristics. A control terminal of each transistor is a gate of the transistor, a first terminal of each transistor is one of a source and a drain of the transistor, and a second terminal of each transistor is the other of the source and the drain of the transistor. Since the source and the drain of a transistor are structurally symmetrical and may be considered to have no difference in structure, the first terminal and the second terminal of the transistor in this embodiment may have no difference in structure. For example, when the transistor is a P-type transistor, the first terminal of the transistor is a source, and the second terminal is a drain. For another example, when the transistor is an N-type transistor, the first terminal of the transistor is a drain, and the second terminal is a source. Illustratively, the N-type transistor and the P-type transistor in this embodiment may adopt oxide thin film transistors, which may be selected according to design requirements and are not specifically limited.

Specifically, the control unit 10 may receive the input signal IN and the first clock signal CK1 to control the potential of the first node Q1 and the potential of the second node Q2, respectively. The control terminal of the first output sub-unit 21 is connected to the first node Q1. The first terminal of the first output sub-unit 21 receives the first voltage signal V1, and when the potential of the first node Q1 is an active-level signal, the first output sub-unit 21 is turned on, and the second terminal of the first output sub-unit 21 outputs the first voltage signal V1, that is, the output signal OUT output by the shift register is the first voltage signal V1. In addition, the control terminal of the second output sub-unit 22 is connected to the second node Q2. The first terminal of the second output sub-unit 22 receives the second voltage signal V2, and when the potential of the second node Q2 is an active-level signal, the second output sub-unit 22 is turned on, and the second terminal of the second output sub-unit 22 outputs the second voltage signal V2, that is, the output signal OUT output by the shift register is the second voltage signal V2. One of the potential of the first node Q1 and the potential of the second node Q2 is a logic high-level signal VGH, and the other of the potential of the first node Q1 and the potential of the second node Q2 is a logic low-level signal VGL. Therefore, when the potential of the first node Q1 is an active-level signal, the potential of the second node Q2 is correspondingly an inactive-level signal. In this case, the second terminal of the first output sub-unit 21 outputs the first voltage signal V1, and the second terminal of the second output sub-unit 22 does not output. That is, the output signal OUT output by the shift register is the first voltage signal V1. When the potential of the first node Q1 is an inactive-level signal, the potential of the second node Q2 is correspondingly an active-level signal. In this case, the second terminal of the second output sub-unit 22 outputs the second voltage signal V2, and the second terminal of the first output sub-unit 21 does not output. That is, the output signal OUT output by the shift register is the second voltage signal V2. On this basis, one of the first voltage signal V1 and the second voltage signal V2 is a logic high-level signal VGH, and the other of the first voltage signal V1 and the second voltage signal V2 is a logic low-level signal VGL, which further indicates that the output signal OUT output by the shift register is either a logic high-level signal VGH or a logic low-level signal VGL, that is, the level signal of the output signal OUT output by the shift register may be switched between logic high level and logic low level.

In addition, the node voltage regulation unit 30 is connected to the first node Q1. The node voltage regulation unit 30 may regulate the magnitude/level of the potential of the first node Q1. Illustratively, the node voltage regulation unit 30 may maintain the potential of the first node Q1 at the active-level signal for the first output sub-unit 21 during at least part of a period in which the potential of the second node Q2 is an inactive-level signal. In a more easily understandable manner, with the configuration of the added node voltage regulation unit 30, the potential of the first node Q1 may be appropriately raised during at least part of a period in which the potential of the first node Q1 is the active-level signal for the first output sub-unit 21 so that the potential of the first node Q1 is more “effective” or guaranteed to be “effective” relative to the turn-on process of the first output sub-unit 21, thereby avoiding the situation in which the first output sub-unit 21 cannot be guaranteed to be turned on after the potential of the first node Q1 changes due to formation of a leakage path and leakage current, thereby ensuring stable output of the first voltage signal V1 corresponding to the output signal OUT. In this process, it is also ensured that the second voltage signal V2 corresponding to the output signal OUT is not output. It can be understood that the active-level signal for the first output sub-unit 21 may be at a logic high level, and the node voltage regulation unit 30 needs to raise the potential of the first node Q1 to offset a drop in the potential of the first node Q1 generated by the leakage current and maintain the potential of the first node Q1 to a potential level corresponding to the turn-on of the first output sub-unit 21. Conversely, the active-level signal for the first output sub-unit 21 may also be at a logic low level, and the node voltage regulation unit 30 needs to pull down the potential of the first node Q1 to offset a rise of the potential of the first node Q1 generated by the leakage current and maintain the potential of the first node Q1 to a potential level corresponding to the turn-on of the first output sub-unit 21. Furthermore, after the potential of the first node Q1 is maintained at the active-level signal for the first output sub-unit 21, the first output sub-unit 21 may be maintained turned on. The first voltage signal V1 corresponding to the first terminal of the first output sub-unit 21 may be continuously transmitted to the second terminal of the first output sub-unit 21. The shift register can stably output the first voltage signal V1, thereby ensuring stable output of the output signal OUT of the shift register.

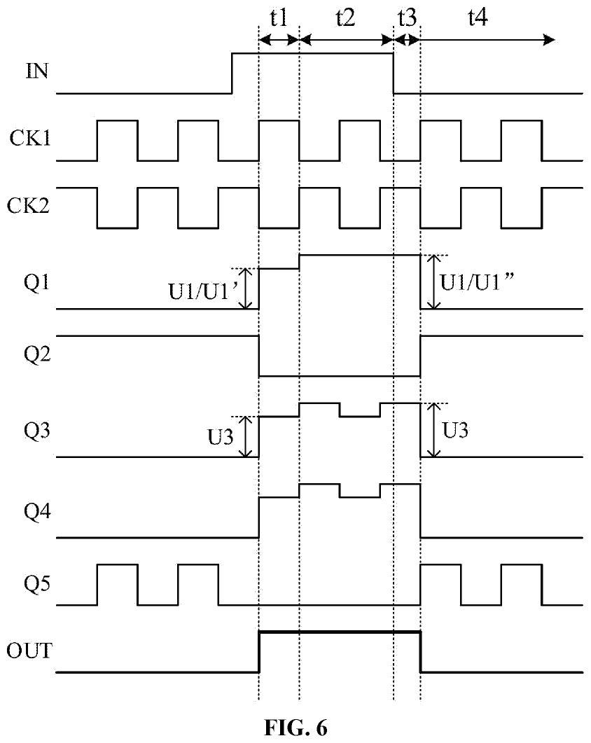

Optionally, FIG. 5 is a schematic diagram illustrating one specific structure of the shift register in the driver circuit shown in FIG. 4. FIG. 6 is a drive timing diagram of each stage of shift register in the driver circuit shown in FIG. 5. As shown in FIG. 5 and FIG. 6, the active-level signal of the first node Q1 is a logic high-level signal VGH, and the potential of the first node Q1 satisfies the following: U1′≤U1″, where U1′ denotes the potential of the first node Q1 in a phase in which the input signal IN is an active-level signal and the first clock signal CK1 first switches to an active-level signal; U1″ denotes the potential of the first node Q1 in a phase in which the input signal IN is an active-level signal and the first clock signal CK1 is an inactive-level signal, or in a phase in which the input signal IN switches from an active-level signal to an inactive-level signal and the first clock signal CK1 is an inactive-level signal.

Specifically, U1′ denotes the potential of the first node Q1 in a phase in which the input signal IN is an active-level signal and the first clock signal CK1 first switches to an active-level signal. U1′ may be understood as the potential of the first node Q1 in phase t1 shown in FIG. 6. U1″ denotes the potential of the first node Q1 in a phase in which the input signal IN is an active-level signal and the first clock signal CK1 is an inactive-level signal. U1″ may be understood as the potential of the first node Q1 in phase t2 shown in FIG. 6. In this case, U1′<U1″, which clearly indicates that the potential of the first node Q1 is raised to offset a drop in the potential of the first node Q1 caused by leakage current. During at least part of a period in which the potential of the second node Q2 is an inactive-level signal, the potential of the first node Q1 may be maintained at the level of the active-level signal for the first output sub-unit 21 to ensure the effective turn-on of the first output sub-unit 21. Of course, when the potential of the first node Q1 is maintained at the level of the active-level signal for the first output sub-unit 21, U1′ may also equal U1″. In addition, U1″ may also be the potential of the first node Q1 in a phase in which the input signal IN switches from an active-level signal to an inactive-level signal and the first clock signal CK1 is an inactive-level signal. U1″ may also be understood as the potential of the first node Q1 in phase t3 shown in FIG. 6. In this case, U1′<U1″, which clearly indicates that the potential of the first node Q1 is raised to offset a drop in the potential of the first node Q1 caused by leakage current. During at least part of a period in which the potential of the second node Q2 is an inactive-level signal, the potential of the first node Q1 may be maintained at the level of the active-level signal for the first output sub-unit 21 to ensure the effective turn-on of the first output sub-unit 21. Of course, when the potential of the first node Q1 is maintained at the level of the active-level signal for the first output sub-unit 21, U1′ may also equal U1″.

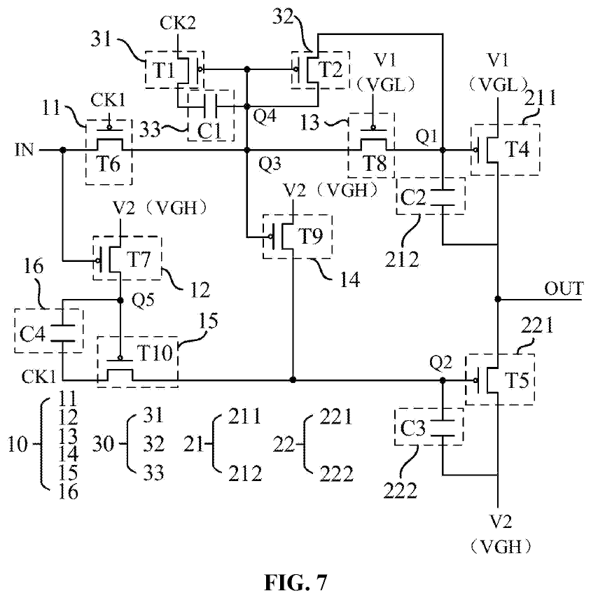

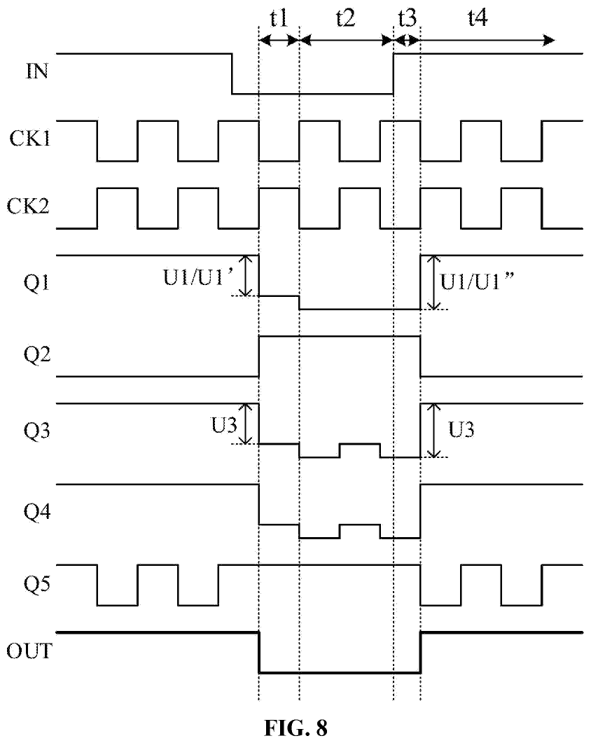

Alternatively or optionally, FIG. 7 is a schematic diagram illustrating another specific structure of the shift register in the driver circuit shown in FIG. 4. FIG. 8 is a drive timing diagram of each stage of shift register in the driver circuit shown in FIG. 7. As shown in FIG. 7 and FIG. 8, the active-level signal of the first node Q1 is a logic low-level signal VGL, and the potential of the first node Q1 satisfies the following: U1′≥U1″, where U1′ denotes the potential of the first node Q1 in a phase in which the input signal IN is an active-level signal and the first clock signal CK1 first switches to an active-level signal; U1″ denotes the potential of the first node Q1 in a phase in which the input signal IN is an active-level signal and the first clock signal CK1 is an inactive-level signal, or in a phase in which the input signal IN switches from an active-level signal to an inactive-level signal and the first clock signal CK1 is an inactive-level signal.

Specifically, related content may refer to the preceding embodiment and is not repeated in this embodiment. In FIG. 8, U1′<U1″, which clearly indicates that the potential of the first node Q1 is pulled down to offset a rise in the potential of the first node Q1 caused by leakage current. During at least part of a period in which the potential of the second node Q2 is an inactive-level signal, the potential of the first node Q1 may be maintained at the level of the active-level signal for the first output sub-unit 21 to ensure the effective turn-on of the first output sub-unit 21. Of course, when the potential of the first node Q1 is maintained at the level of the active-level signal for the first output sub-unit 21, U1′ may also equal U1″.

Optionally, with continued reference to FIG. 5 and FIG. 7, the control unit 10 includes a third node Q3. One of the potential of the third node Q3 and the potential of the second node Q2 is a logic high-level signal VGH, and the other of the potential of the third node Q3 and the potential of the second node Q2 is a logic low-level signal VGL. A control terminal of the node voltage regulation unit 30 is connected to the third node Q3. The node voltage regulation unit 30 is configured to maintain the potential of the first node Q1 at the active-level signal for the first output sub-unit 21 during at least part of a period in which the potential of the third node Q3 is an active-level signal.

Specifically, the control terminal of the node voltage regulation unit 30 is connected to the third node Q3, and the node voltage regulation unit 30 is also connected to the first node Q1. Therefore, the potential of the third node Q3 may control the turn-on and turn-off of the node voltage regulation unit 30, thereby affecting the potential of the first node Q1. Illustratively, when the potential of the third node Q3 is an active-level signal, the node voltage regulation unit 30 is correspondingly turned on, and the node voltage regulation unit 30 may regulate the potential magnitude/level of the first node Q1 so that the potential of the first node Q1 is maintained at the level of the active-level signal for the first output sub-unit 21. In addition, one of the potential of the third node Q3 and the potential of the second node Q2 is a logic high-level signal VGH, and the other of the potential of the third node Q3 and the potential of the second node Q2 is a logic low-level signal VGL. Therefore, when the potential of the third node Q3 is an active-level signal, the potential of the second node Q2 is correspondingly an inactive-level signal, and the potential of the first node Q1 is correspondingly an active-level signal. In this case, the second terminal of the first output sub-unit 21 outputs the first voltage signal V1, and the second terminal of the second output sub-unit 22 does not output. That is, the output signal OUT output by the shift register is the first voltage signal V1. When the potential of the third node Q3 is an inactive-level signal, the potential of the second node Q2 is correspondingly an active-level signal, and the potential of the first node Q1 is correspondingly an inactive-level signal. In this case, the second terminal of the second output sub-unit 22 outputs the second voltage signal V2, and the second terminal of the first output sub-unit 21 does not output. That is, the output signal OUT output by the shift register is the second voltage signal V2.

Optionally, with continued reference to FIG. 5 and FIG. 6, the active-level signal of the first node Q1 is a logic high-level signal VGH. In a phase in which the first node Q1 is at the active-level signal, U1≥U3, where U1 denotes the potential of the first node Q1, and U3 denotes the potential of the third node Q3.

Specifically, in phase t1 shown in FIG. 6, it can be clearly seen that U1=U3. In phase t2 shown in FIG. 6, it can be clearly seen that U1=U3, or U1>U3. In phase t3 shown in FIG. 6, it can be clearly seen that U1=U3. It can be understood that when U1≥U3, the potential of the first node Q1 is clearly raised, which can offset a drop of the potential of the first node Q1 generated by leakage current and maintain the potential of the first node Q1 to a potential level corresponding to the turn-on of the first output sub-unit 21 so that the first output sub-unit 21 is effectively turned on, and the output signal OUT corresponding to the shift register stably outputs the first voltage signal V1.

Alternatively or optionally, with continued reference to FIG. 7 and FIG. 8, the active-level signal of the first node Q1 is a logic low-level signal VGL. In a phase in which the first node Q1 is at the active-level signal, U1≤U3, where U1 denotes the potential of the first node Q1, and U3 denotes the potential of the third node Q3.

Specifically, related content may refer to the preceding embodiment and is not repeated in this embodiment. In phase t1 shown in FIG. 8, it can be clearly seen that U1=U3. In phase t2 shown in FIG. 8, it can be clearly seen that U1=U3, or U1<U3. In phase t3 shown in FIG. 8, it can be clearly seen that U1=U3. It can be understood that when U1≤U3, the potential of the first node Q1 is clearly pulled down, which can offset a rise of the potential of the first node Q1 generated by leakage current and maintain the potential of the first node Q1 to a potential level corresponding to the turn-on of the first output sub-unit 21 so that the first output sub-unit 21 is effectively turned on, and the output signal OUT corresponding to the shift register stably outputs the first voltage signal V1.

Optionally, with continued reference to FIG. 5 and FIG. 7, the node voltage regulation unit 30 includes a first switching sub-unit 31, a second switching sub-unit 32, and a first energy storage sub-unit 33. A first terminal of the first switching sub-unit 31 receives a second clock signal CK2, and a second terminal of the first switching sub-unit 31 is connected to a first terminal of the first energy storage sub-unit 33. A second terminal of the first energy storage sub-unit 33, a control terminal of the first switching sub-unit 31, a first terminal of the second switching sub-unit 32, and a control terminal of the second switching sub-unit 32 are connected to a fourth node Q4. The fourth node Q4 is connected to the third node Q3. A second terminal of the second switching sub-unit 32 is connected to the first node Q1. The second clock signal CK2 and the first clock signal CK1 are inverted in phase. The first switching sub-unit 31 and the second switching sub-unit 32 are configured to be turned on when the potential of the third node Q3 is an active-level signal. The first energy storage sub-unit 33 is configured to receive the second clock signal CK2 for charging when the first clock signal CK1 is an active-level signal, and to discharge to the first node Q1 through the turned-on second switching sub-unit 32 when the first clock signal CK1 switches from an active-level signal to an inactive-level signal, to maintain the potential of the first node Q1.

Specifically, the first terminal of the first switching sub-unit 31 receives the second clock signal CK2, and the second terminal of the first switching sub-unit 31 is connected to the first terminal of the first energy storage sub-unit 33. The control terminal of the first switching sub-unit 31 is connected to the fourth node Q4. The fourth node Q4 is connected to the third node Q3. Therefore, the first switching sub-unit 31 may be turned on or turned off under the action of the potential of the fourth node Q4, the potential magnitude of the third node Q3 affects the potential magnitude of the fourth node Q4, and the potential magnitude of the fourth node Q4 affects the potential magnitude of the third node Q3. Illustratively, the first switching sub-unit 31 may be turned on when the potential of the third node Q3 is an active-level signal. In this case, the fourth node Q4 is also at an active-level signal. In addition, the first terminal of the second switching sub-unit 32 is connected to the fourth node Q4, the second terminal of the second switching sub-unit 32 is connected to the first node Q1, and the control terminal of the second switching sub-unit 32 is connected to the fourth node Q4. Therefore, the second switching sub-unit 32 may be turned on or turned off under the action of the potential of the fourth node Q4. The potential magnitude of the third node Q3 affects the potential magnitude of the fourth node Q4. The potential magnitude of the fourth node Q4 affects the potential magnitude of the third node Q3. Illustratively, the second switching sub-unit 32 may be turned on when the potential of the third node Q3 is an active-level signal. In this case, the fourth node Q4 is also at an active-level signal.

The first terminal of the first energy storage sub-unit 33 is connected to the second terminal of the first switching sub-unit 31, and the second terminal of the first energy storage sub-unit 33 is connected to the fourth node Q4. The first energy storage sub-unit 33 may maintain the voltage across the first energy storage sub-unit 33 stable, that is, the voltage difference across the first energy storage sub-unit 33 remains unchanged. The first energy storage sub-unit 33 may change the potential magnitude of the fourth node Q4 through a charging and discharging process, thereby changing the potential magnitude of the third node Q3. The second clock signal CK2 and the first clock signal CK1 are inverted in phase. Therefore, when the first clock signal CK1 is an active-level signal, the second clock signal CK2 is correspondingly an inactive-level signal. Illustratively, when the first clock signal CK1 is an active-level signal, the third node Q3 is also at an active-level signal. Therefore, both the first switching sub-unit 31 and the second switching sub-unit 32 are turned on. When the first clock signal CK1 is an inactive-level signal, the third node Q3 is floating, and the potential of the third node Q3 maintains the state of the previous phase, that is, the third node Q3 is still at an active-level signal, and both the first switching sub-unit 31 and the second switching sub-unit 32 remain turned on. That is, the first energy storage sub-unit 33 may receive the second clock signal CK2 for charging when the first clock signal CK1 is an active-level signal. The first energy storage sub-unit 33 may also discharge to the first node Q1 through the turned-on second switching sub-unit 32 when the first clock signal CK1 switches from an active-level signal to an inactive-level signal, to maintain the potential of the first node Q1. That is, the potential of the first node Q1 is maintained through the discharging process of the first energy storage sub-unit 33, and the charging power of the first energy storage sub-unit 33 comes from the potential signal of the second clock signal CK2. Illustratively, in a discharging process of the first energy storage sub-unit 33 shown in FIG. 5, the potential of the first node Q1 is clearly raised to achieve bootstrapping of the first node Q1, which can offset a drop of the potential of the first node Q1 generated by leakage current and maintain the potential of the first node Q1 to a potential level corresponding to the turn-on of the first output sub-unit 21 so that the first output sub-unit 21 is effectively turned on, and the output signal OUT corresponding to the shift register stably outputs the first voltage signal V1. In addition, illustratively, in a discharging process of the first energy storage sub-unit 33 shown in FIG. 7, the potential of the first node Q1 is clearly pulled down to achieve bootstrapping of the first node Q1, which can offset a rise of the potential of the first node Q1 generated by leakage current and maintain the potential of the first node Q1 to a potential level corresponding to the turn-on of the first output sub-unit 21 so that the first output sub-unit 21 is effectively turned on, and the output signal OUT corresponding to the shift register stably outputs the first voltage signal V1.

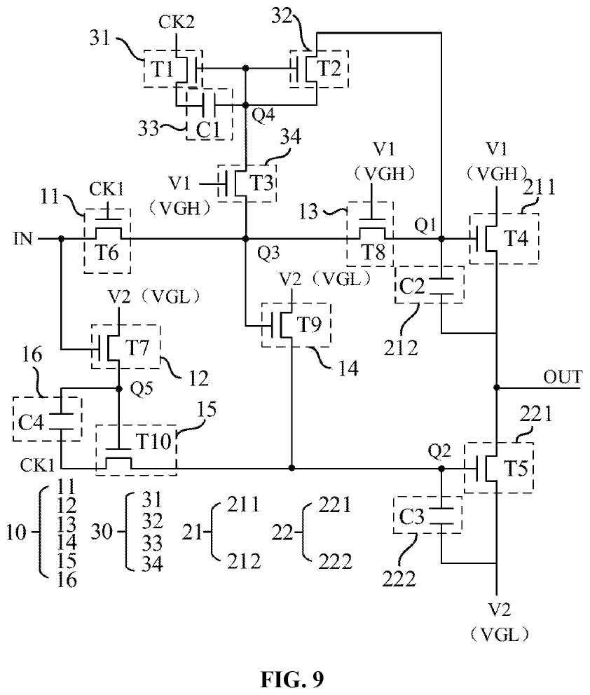

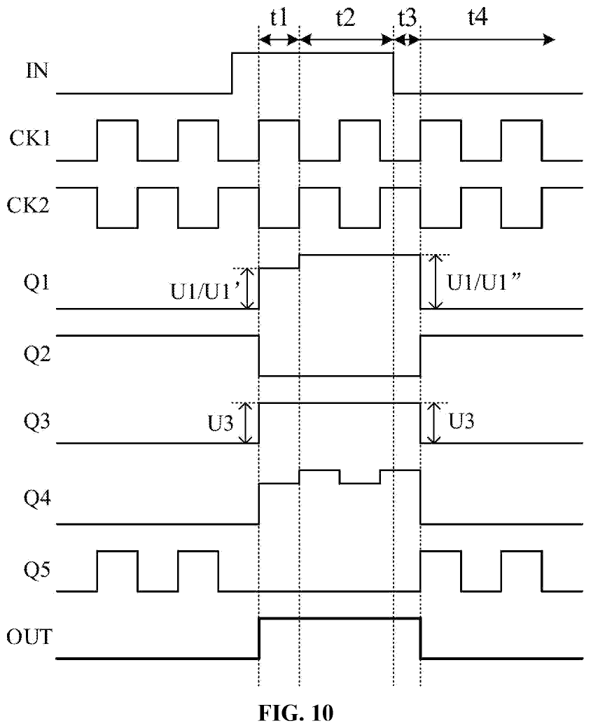

Optionally, FIG. 9 is a schematic diagram illustrating another specific structure of the shift register in the driver circuit shown in FIG. 4, and FIG. 10 is a drive timing diagram of each stage of shift register in the driver circuit shown in FIG. 9. As shown in FIG. 9 and FIG. 10, the node voltage regulation unit 30 also includes a third switching sub-unit 34, and the third switching sub-unit 34 is connected between the fourth node Q4 and the third node Q3. A control terminal of the third switching sub-unit 34 receives the first voltage signal V1.

Specifically, the control terminal of the third switching sub-unit 34 receives the first voltage signal V1, a first terminal of the third switching sub-unit 34 is connected to the fourth node Q4, and a second terminal of the third switching sub-unit 34 is connected to the third node Q3. Therefore, the third switching sub-unit 34 may be turned on or turned off under the action of the potential of the first voltage signal V1. Illustratively, if the first voltage signal V1 is an active-level signal, the third switching sub-unit 34 is constantly turned on. If the first voltage signal V1 is an inactive-level signal, the third switching sub-unit 34 is constantly turned off. Illustratively, the third switching sub-unit 34 may also be switched between a constantly-on state and a constantly-off state by reasonably adjusting the first voltage signal V1 to be a logic high-level signal VGH or a logic low-level signal VGL. It can be understood that the arrangement of the third switching sub-unit 34 may effectively prevent leakage current from the fourth node Q4 toward the third node Q3 and other transistors and block transmission of leakage current between the fourth node Q4 and the third node Q3.

Further, with continued reference to FIG. 5 and FIG. 9, the first switching sub-unit 31 includes a first transistor T1, the second switching sub-unit 32 includes a second transistor T2, the third switching sub-unit 34 includes a third transistor T3, and the first energy storage sub-unit 33 includes a first capacitor C1. A first electrode of the first transistor T1 receives the second clock signal CK2, and a second electrode of the first transistor T1 is connected to a first plate of the first capacitor C1. A second plate of the first capacitor C1, a gate of the first transistor T1, a gate of the second transistor T2, and a first electrode of the second transistor T2 are all connected to the fourth node Q4. A second electrode of the second transistor T2 is connected to the first node Q1. The third transistor T3 is connected between the fourth node Q4 and the third node Q3. A first electrode of the third transistor T3 is connected to the fourth node Q4, a second electrode of the third transistor T3 receives the input signal IN, and a gate of the third transistor T3 receives the first voltage signal V1. The first transistor T1, the second transistor T2, and the third transistor T3 have the same channel type.

The first transistor T1, the second transistor T2, and the third transistor T3 have the same channel type. Optionally, the first transistor T1, the second transistor T2, and the third transistor T3 are all N-channel transistors. Then, active-level signals corresponding to the first transistor T1, the second transistor T2, and the third transistor T3 are all at a logic high level, and the first transistor T1, the second transistor T2, and the third transistor T3 may be turned on under the action of a logic high-level potential. Inactive-level signals corresponding to the first transistor T1, the second transistor T2, and the third transistor T3 are all at a logic low level, and the first transistor T1, the second transistor T2, and the third transistor T3 may be turned off under the action of a logic low-level potential. Illustratively, active-level signals of the third node Q3 and the fourth node Q4 may be a logic high-level signal VGH, inactive-level signals of the third node Q3 and the fourth node Q4 may be a logic low-level signal VGL, an active-level signal of the first clock signal CK1 may be a logic high-level signal VGH, and an inactive-level signal of the first clock signal CK1 may be a logic low-level signal VGL. Specifically, when the first clock signal CK1 is an active-level signal, that is, when the first clock signal CK1 is at a logic high level, the potentials of the third node Q3 and the fourth node Q4 may also be at a logic high level. Then, the first transistor T1 and the second transistor T2 are turned on, the third transistor T3 is constantly turned on, and the first capacitor C1 may receive the second clock signal CK2 for charging. When the first clock signal CK1 switches from an active-level signal to an inactive-level signal, that is, when the first clock signal CK1 is converted from a logic high level to a logic low level, the third node Q3 and the fourth node Q4 are floating, and the potentials of the third node Q3 and the fourth node Q4 maintain the state of the previous phase, that is, the potentials of the third node Q3 and the fourth node Q4 are still at a logic high level. The first transistor T1 and the second transistor T2 remain turned on. Then, the first capacitor C1 may discharge to the first node Q1 through the turned-on second transistor T2 to raise the potential of the first node Q1 and keep the first output sub-unit 21 turned on.

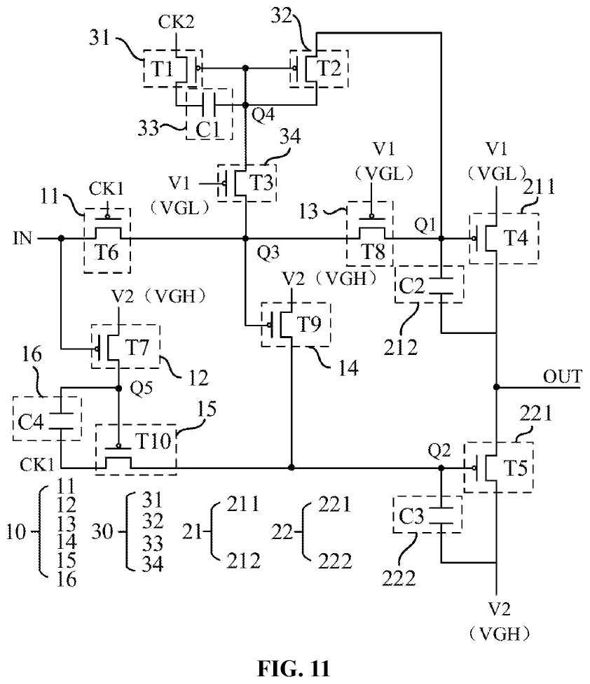

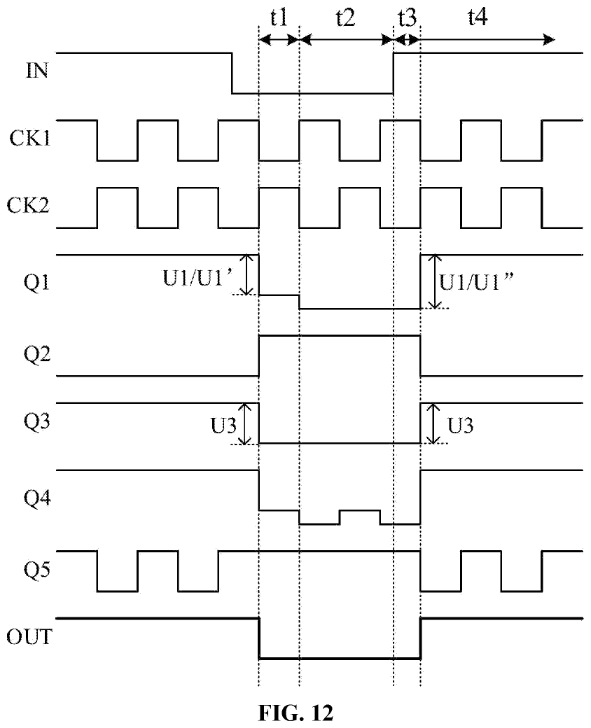

In another specific embodiment, the first transistor T1, the second transistor T2, and the third transistor T3 have the same channel type. Optionally, FIG. 11 is a schematic diagram illustrating another specific structure of the shift register in the driver circuit shown in FIG. 4, and FIG. 12 is a drive timing diagram of each stage of shift register in the driver circuit shown in FIG. 11. As shown in FIG. 7, FIG. 11, and FIG. 12, the first transistor T1, the second transistor T2, and the third transistor T3 are all P-channel transistors. Related content may refer to the preceding embodiments and is not repeated in this embodiment.

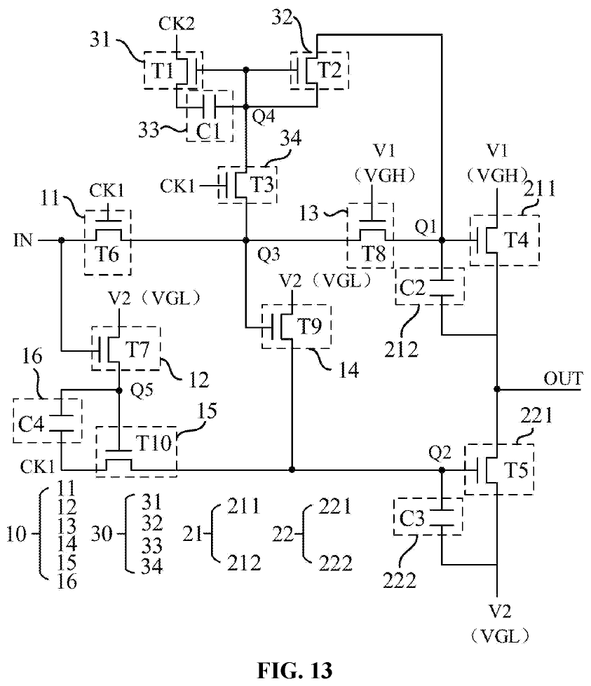

Alternatively or optionally, FIG. 13 is a schematic diagram illustrating another specific structure of the shift register in the driver circuit shown in FIG. 4. As shown in FIG. 13, the node voltage regulation unit 30 also includes a third switching sub-unit 34, and the third switching sub-unit 34 is connected between the fourth node Q4 and the third node Q3. A control terminal of the third switching sub-unit 34 receives the first clock signal CK1.

Specifically, the control terminal of the third switching sub-unit 34 receives the first clock signal CK1, a first terminal of the third switching sub-unit 34 is connected to the fourth node Q4, and a second terminal of the third switching sub-unit 34 is connected to the third node Q3. Therefore, the third switching sub-unit 34 may be turned on or turned off under the action of the potential of the first clock signal CK1. Illustratively, if the first clock signal CK1 is an active-level signal, the third switching sub-unit 34 is constantly turned on. If the first clock signal CK1 is an inactive-level signal, the third switching sub-unit 34 is constantly turned off. Illustratively, the third switching sub-unit 34 may switch between a constantly-on state and a constantly-off state along with the active-level signal and the inactive-level signal of the first clock signal CK1. It can be understood that the arrangement of the third switching sub-unit 34 may effectively prevent leakage current from the fourth node Q4 toward the third node Q3 and other transistors and block transmission of leakage current between the fourth node Q4 and the third node Q3.

Further, with continued reference to FIG. 5 and FIG. 13, the first switching sub-unit 31 includes a first transistor T1, the second switching sub-unit 32 includes a second transistor T2, the third switching sub-unit 34 includes a third transistor T3, and the first energy storage sub-unit 33 includes a first capacitor C1. A first electrode of the first transistor T1 receives the second clock signal CK2, and a second electrode of the first transistor T1 is connected to a first plate of the first capacitor C1. A second plate of the first capacitor C1, a gate of the first transistor T1, a gate of the second transistor T2, and a first electrode of the second transistor T2 are all connected to the fourth node Q4. A second electrode of the second transistor T2 is connected to the first node Q1. The third transistor T3 is connected between the fourth node Q4 and the third node Q3. A first electrode of the third transistor T3 is connected to the fourth node Q4, a second electrode of the third transistor T3 receives the input signal IN, and a gate of the third transistor T3 receives the first clock signal CK1. The first transistor T1, the second transistor T2, and the third transistor T3 have the same channel type.

The first transistor T1, the second transistor T2, and the third transistor T3 have the same channel type. Optionally, the first transistor T1, the second transistor T2, and the third transistor T3 are all N-channel transistors. Related content may refer to the preceding embodiments and is not repeated in this embodiment. It is also to be noted that when the first clock signal CK1 is an active-level signal, that is, when the first clock signal CK1 is at a logic high level, the potentials of the third node Q3 and the fourth node Q4 may also be at a logic high level. Then, the first transistor T1 and the second transistor T2 are turned on, and the third transistor T3 is also turned on under the action of the logic high level of the first clock signal CK1. The first capacitor C1 may receive the second clock signal CK2 for charging. When the first clock signal CK1 switches from an active-level signal to an inactive-level signal, that is, when the first clock signal CK1 is converted from a logic high level to a logic low level, the third node Q3 and the fourth node Q4 are floating, and the potentials of the third node Q3 and the fourth node Q4 maintain the state of the previous phase, that is, the potentials of the third node Q3 and the fourth node Q4 are still at a logic high level. The first transistor T1 and the second transistor T2 remain turned on, and the third transistor T3 is turned off under the action of the logic low level of the first clock signal CK1. Then, the first capacitor C1 may discharge to the first node Q1 through the turned-on second transistor T2 to raise the potential of the first node Q1 and keep the first output sub-unit 21 turned on. In addition, the turn-off of the third transistor T3 in this case enables the potential of the fourth node Q4 to be more stable. The fourth node Q4 cannot form a leakage path toward the third node Q3 through the third transistor T3. The first capacitor C1 may discharge toward the first node Q1 through the fourth node Q4 and the second transistor T2, which effectively reduces discharge loss, further stabilizes the potential of the first node Q1, and ensures the effective turn-on of the first output sub-unit 21.

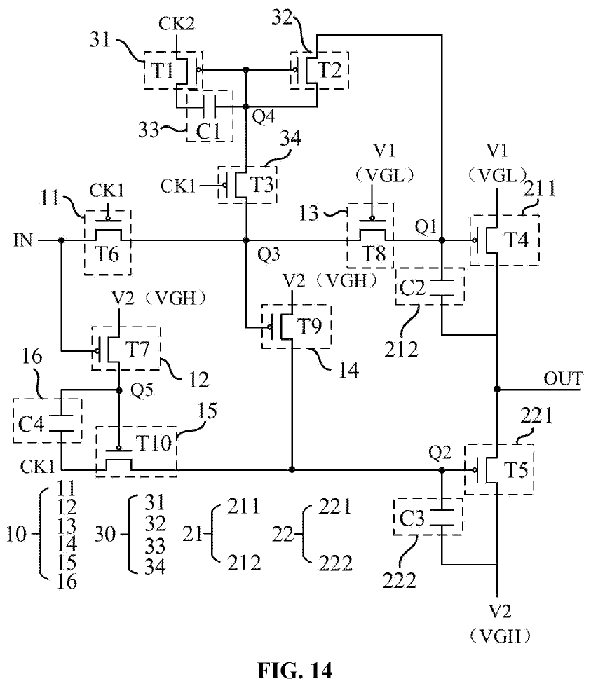

In another embodiment, the first transistor T1, the second transistor T2, and the third transistor T3 have the same channel type. Optionally, FIG. 14 is a schematic diagram illustrating another specific structure of the shift register in the driver circuit shown in FIG. 4. As shown in FIG. 7 and FIG. 14, the first transistor T1, the second transistor T2, and the third transistor T3 are all P-channel transistors. Related content may refer to the preceding embodiments and is not repeated in this embodiment.

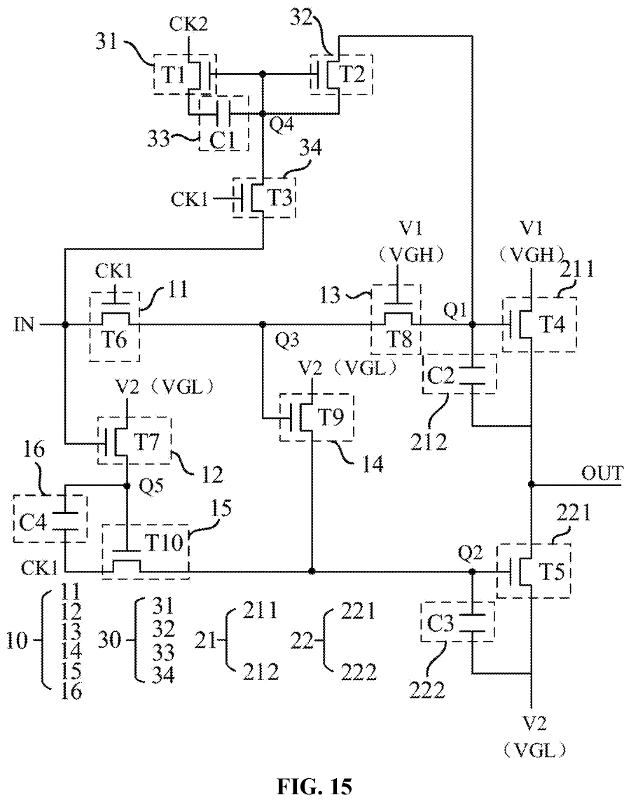

Optionally, FIG. 15 is a schematic diagram illustrating another specific structure of the shift register in the driver circuit shown in FIG. 4. As shown in FIG. 15, a control terminal of the node voltage regulation unit 30 receives the input signal IN, and the node voltage regulation unit 30 is configured to maintain the potential of the first node Q1 at the active-level signal for the first output sub-unit 21 at least during a period in which the potential of the input signal IN is an active-level signal and the first clock signal CK1 is an inactive-level signal.

Specifically, the control terminal of the node voltage regulation unit 30 receives the input signal IN, and the node voltage regulation unit 30 is also connected to the first node Q1. Therefore, the node voltage regulation unit 30 may regulate the potential magnitude/level of the first node Q1 according to the received input signal IN. Illustratively, the node voltage regulation unit 30 may maintain the potential of the first node Q1 at the active-level signal for the first output sub-unit 21 at least during a period in which the potential of the input signal IN is an active-level signal and the first clock signal CK1 is an inactive-level signal. In a more easily understandable manner, with the configuration of the added node voltage regulation unit 30, floating of the potential of the first node Q1 caused by the first clock signal CK1 being an inactive-level signal may be reduced during a period in which the potential of the input signal IN is an active-level signal and the first clock signal CK1 is an inactive-level signal. The potential of the first node Q1 may be appropriately raised so that the potential of the first node Q1 is more “effective” or guaranteed to be “effective” relative to the turn-on process of the first output sub-unit 21, thereby avoiding the situation in which the first output sub-unit 21 cannot be guaranteed to be turned on after the potential of the first node Q1 changes due to formation of a leakage path and leakage current, thereby ensuring stable output of the first voltage signal V1 corresponding to the output signal OUT. In this process, it is also ensured that the second voltage signal V2 corresponding to the output signal OUT is not output. It can be understood that the active-level signal for the first output sub-unit 21 may be at a logic high level, and the node voltage regulation unit 30 needs to raise the potential of the first node Q1 to offset a drop in the potential of the first node Q1 generated by the leakage current and maintain the potential of the first node Q1 to a potential level corresponding to the turn-on of the first output sub-unit 21. Conversely, the active-level signal for the first output sub-unit 21 may also be at a logic low level, and the node voltage regulation unit 30 needs to pull down the potential of the first node Q1 to offset a rise of the potential of the first node Q1 generated by the leakage current and maintain the potential of the first node Q1 to a potential level corresponding to the turn-on of the first output sub-unit 21. Furthermore, after the potential of the first node Q1 is maintained at the active-level signal for the first output sub-unit 21, the first output sub-unit 21 may be maintained turned on. The first voltage signal V1 corresponding to the first terminal of the first output sub-unit 21 may be continuously transmitted to the second terminal of the first output sub-unit 21. The shift register can stably output the first voltage signal V1, thereby ensuring stable output of the output signal OUT of the shift register.

Optionally, with continued reference to FIG. 15, the node voltage regulation unit 30 includes a first switching sub-unit 31, a second switching sub-unit 32, a third switching sub-unit 34, and a first energy storage sub-unit 33. A first terminal of the first switching sub-unit 31 receives a second clock signal CK2, and a second terminal of the first switching sub-unit 31 is connected to a first terminal of the first energy storage sub-unit 33. A second terminal of the first energy storage sub-unit 33, a control terminal of the first switching sub-unit 31, a first terminal of the second switching sub-unit 32, and a control terminal of the second switching sub-unit 32 are connected to a fourth node Q4. A second terminal of the second switching sub-unit 32 is connected to the first node Q1. The second clock signal CK2 and the first clock signal CK1 are inverted in phase. A first terminal of the third switching sub-unit 34 is connected to the fourth node Q4, a second terminal of the third switching sub-unit 34 receives the input signal IN, and a control terminal of the third switching sub-unit 34 receives the first clock signal CK1. The third switching sub-unit 34 is configured to be turned on when the first clock signal CK1 is an active-level signal. The first switching sub-unit 31 and the second switching sub-unit 32 are configured to be turned on when the input signal IN is an active-level signal. The first energy storage sub-unit 33 is configured to receive the second clock signal CK2 and the input signal IN at two terminals of the first energy storage sub-unit 33 for charging when the first clock signal CK1 is an active-level signal, and the first energy storage sub-unit 33 is configured to discharge to the first node Q1 through the turned-on second switching sub-unit 32 when the first clock signal CK1 is an inactive-level signal, to maintain the potential of the first node Q1.

Specifically, the first terminal of the third switching sub-unit 34 is connected to the fourth node Q4, the second terminal of the third switching sub-unit 34 receives the input signal IN, and the control terminal of the third switching sub-unit 34 receives the first clock signal CK1. Therefore, the third switching sub-unit 34 may be turned on or turned off under the action of the potential of the first clock signal CK1. Illustratively, the third switching sub-unit 34 may be turned on when the first clock signal CK1 is an active-level signal. In this case, the input signal IN corresponding to the second terminal of the third switching sub-unit 34 may be transmitted to the fourth node Q4, and the potential at the fourth node Q4 is the potential of the input signal IN. In addition, the first terminal of the first switching sub-unit 31 receives the second clock signal CK2, the second terminal of the first switching sub-unit 31 is connected to the first terminal of the first energy storage sub-unit 33, and the control terminal of the first switching sub-unit 31 is connected to the fourth node Q4. Therefore, the first switching sub-unit 31 may be turned on or turned off under the action of the potential of the fourth node Q4. Illustratively, after the third switching sub-unit 34 is turned on, the first switching sub-unit 31 may also be turned on or turned off under the action of the potential of the input signal IN. In addition, the first terminal of the second switching sub-unit 32 is connected to the fourth node Q4, the second terminal of the second switching sub-unit 32 is connected to the first node Q1, and the control terminal of the second switching sub-unit 32 is connected to the fourth node Q4. Therefore, the second switching sub-unit 32 may be turned on or turned off under the action of the potential of the fourth node Q4. Illustratively, after the third switching sub-unit 34 is turned on, the second switching sub-unit 32 may also be turned on or turned off under the action of the potential of the input signal IN.

The first terminal of the first energy storage sub-unit 33 is connected to the second terminal of the first switching sub-unit 31, and the second terminal of the first energy storage sub-unit 33 is connected to the fourth node Q4. The first energy storage sub-unit 33 may maintain the voltage across the first energy storage sub-unit 33 stable, that is, the voltage difference across the first energy storage sub-unit 33 remains unchanged. The first energy storage sub-unit 33 may change the potential magnitude of the fourth node Q4 through a charging and discharging process. The second clock signal CK2 and the first clock signal CK1 are inverted in phase. Therefore, when the first clock signal CK1 is an active-level signal, the second clock signal CK2 is correspondingly an inactive-level signal. Illustratively, when the first clock signal CK1 is an active-level signal, the third switching sub-unit 34 is turned on, and when the input signal IN is an active-level signal, both the first switching sub-unit 31 and the second switching sub-unit 32 are turned on. When the first clock signal CK1 is an inactive-level signal, the third switching sub-unit 34 is turned off, the fourth node Q4 is floating, and the potential of the fourth node Q4 maintains the state of the previous phase, that is, the fourth node Q4 is still at an active-level signal, and both the first switching sub-unit 31 and the second switching sub-unit 32 remain turned on. That is, the first energy storage sub-unit 33 may receive the second clock signal CK2 and the input signal IN at two terminals of the first energy storage sub-unit 33 for charging when the first clock signal CK1 is an active-level signal. The first energy storage sub-unit 33 may also discharge to the first node Q1 through the turned-on second switching sub-unit 32 when the first clock signal CK1 is an inactive-level signal, to maintain the potential of the first node Q1. That is, the potential of the first node Q1 is maintained through the discharging process of the first energy storage sub-unit 33, and the charging power of the first energy storage sub-unit 33 comes from the potential signal of the second clock signal CK2 and the potential signal of the input signal IN. Illustratively, in a discharging process of the first energy storage sub-unit 33 shown in FIG. 15, the potential of the first node Q1 is clearly raised to achieve bootstrapping of the first node Q1, which can offset a drop of the potential of the first node Q1 generated by leakage current and maintain the potential of the first node Q1 to a potential level corresponding to the turn-on of the first output sub-unit 21 so that the first output sub-unit 21 is effectively turned on, and the output signal OUT corresponding to the shift register stably outputs the first voltage signal V1.

It is also to be noted that with continued reference to FIG. 15, the following are limited in this embodiment: The control terminal of the node voltage regulation unit 30 receives the input signal IN, a third switching sub-unit 34 is disposed between the fourth node Q4 and the input signal IN, and the third switching sub-unit 34 may be turned on or turned off corresponding to a transition process of the active-level signal and the inactive-level signal of the first clock signal CK1. In this manner, it is ensured that the first energy storage sub-unit 33 performs a charging process when the third switching sub-unit 34 is turned on and first energy storage sub-unit 33 performs a discharging process when the third switching sub-unit 34 is turned off, so as to maintain the potential of the first node Q1. If the third switching sub-unit 34 is not disposed between the fourth node Q4 and the input signal IN, the potential of the fourth node Q4 changes completely synchronously with the potential of the input signal IN, the charging and discharging process of the first energy storage sub-unit 33 and the bootstrapping of the first node Q1 cannot be achieved, and the first output sub-unit 21 cannot be kept in an effective on state.

Further, with continued reference to FIG. 15, the first switching sub-unit 31 includes a first transistor T1, the second switching sub-unit 32 includes a second transistor T2, the third switching sub-unit 34 includes a third transistor T3, and the first energy storage sub-unit 33 includes a first capacitor C1. A first electrode of the first transistor T1 receives the second clock signal CK2, and a second electrode of the first transistor T1 is connected to a first plate of the first capacitor C1. A second plate of the first capacitor C1, a gate of the first transistor T1, a gate of the second transistor T2, and a first electrode of the second transistor T2 are all connected to the fourth node Q4. A second electrode of the second transistor T2 is connected to the first node Q1. A first electrode of the third transistor T3 is connected to the fourth node Q4, a second electrode of the third transistor T3 receives the input signal IN, and a gate of the third transistor T3 receives the first clock signal CK1. The first transistor T1, the second transistor T2, and the third transistor T3 have the same channel type.

The first transistor T1, the second transistor T2, and the third transistor T3 have the same channel type. Optionally, the first transistor T1, the second transistor T2, and the third transistor T3 are all N-channel transistors. Then, active-level signals corresponding to the first transistor T1, the second transistor T2, and the third transistor T3 are all at a logic high level, and the first transistor T1, the second transistor T2, and the third transistor T3 may be turned on under the action of a logic high-level potential. Inactive-level signals corresponding to the first transistor T1, the second transistor T2, and the third transistor T3 are all at a logic low level, and the first transistor T1, the second transistor T2, and the third transistor T3 may be turned off under the action of a logic low-level potential. Illustratively, an active-level signal of the fourth node Q4 may be a logic high-level signal VGH, an inactive-level signal of the fourth node Q4 may be a logic low-level signal VGL, an active-level signal of the first clock signal CK1 may be a logic high-level signal VGH, an inactive-level signal of the first clock signal CK1 may be a logic low-level signal VGL, an active-level signal of the input signal IN may be a logic high-level signal VGH, and an inactive-level signal of the input signal IN may be a logic low-level signal VGL. Specifically, when the first clock signal CK1 is an active-level signal, that is, when the first clock signal CK1 is at a logic high level, the third transistor T3 is turned on, the input signal IN corresponding to the second terminal of the third transistor T3 may be transmitted to the fourth node Q4, and the potential at the fourth node Q4 is the potential of the input signal IN. In addition, when the input signal IN is an active-level signal, that is, when the input signal IN is at a logic high level, the first transistor T1 and the second transistor T2 are turned on, and the first capacitor C1 may receive the second clock signal CK2 and the input signal IN for charging. When the first clock signal CK1 is an inactive-level signal, that is, when the first clock signal CK1 is at a logic low level, the fourth node Q4 is floating, and the potential of the fourth node Q4 maintains the state of the previous phase, that is, the fourth node Q4 is still at a logic high level. The first transistor T1 and the second transistor T2 remain turned on. Then, the first capacitor C1 may discharge to the first node Q1 through the turned-on second transistor T2 to raise the potential of the first node Q1 and keep the first output sub-unit 21 turned on.

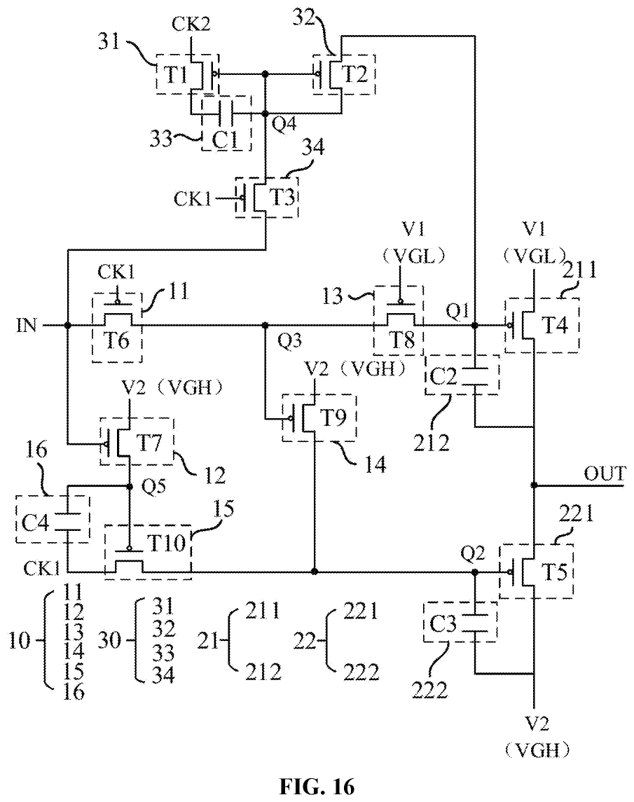

In another embodiment, the first transistor T1, the second transistor T2, and the third transistor T3 have the same channel type. Optionally, FIG. 16 is a schematic diagram illustrating another specific structure of the shift register in the driver circuit shown in FIG. 4. As shown in FIG. 16, the first transistor T1, the second transistor T2, and the third transistor T3 are all P-channel transistors. Related content may refer to the preceding embodiments and is not repeated in this embodiment.

Optionally, with continued reference to FIG. 5, FIG. 7, FIG. 9, FIG. 11, FIG. 13 to FIG. 16, the first output sub-unit 21 includes a fourth switching sub-unit 211 and a second energy storage sub-unit 212, and the second output sub-unit 22 includes a fifth switching sub-unit 221 and a third energy storage sub-unit 222. A first terminal of the fourth switching sub-unit 211 receives the first voltage signal V1, and a control terminal of the fourth switching sub-unit 211 and a first terminal of the second energy storage sub-unit 212 are both connected to the first node Q1. A first terminal of the fifth switching sub-unit 221 receives the second voltage signal V2, and a control terminal of the fifth switching sub-unit 221 and a first terminal of the third energy storage sub-unit 222 are both connected to the second node Q2. A second terminal of the fourth switching sub-unit 211, a second terminal of the second energy storage sub-unit 212, a second terminal of the fifth switching sub-unit 221, and a second terminal of the third energy storage sub-unit 222 are connected to each other and output the output signal OUT. The fourth switching sub-unit 211 is configured to be turned on when the first node Q1 is at an active-level signal. The second energy storage sub-unit 212 is configured to charge at least when the first clock signal CK1 is an active-level signal, and to discharge to the first node Q1 when the first clock signal CK1 switches from an active-level signal to an inactive-level signal, to maintain the potential of the first node Q1. The fifth switching sub-unit 221 is configured to be turned on when the second node Q2 is at an active-level signal. The third energy storage sub-unit 222 is configured to charge at least when the first clock signal CK1 is an inactive-level signal, and the third energy storage sub-unit 222 is configured to discharge to the second node Q2 when the first clock signal CK1 switches from an inactive-level signal to an active-level signal, to maintain the potential of the second node Q2.

Specifically, the first output sub-unit 21 includes the fourth switching sub-unit 211 and the second energy storage sub-unit 212. A control terminal of the fourth switching sub-unit 211 is connected to the first node Q1, a first terminal of the fourth switching sub-unit 211 receives the first voltage signal V1, and a second terminal of the fourth switching sub-unit 211 may output the output signal OUT. In this manner, the fourth switching sub-unit 211 can be turned on or turned off under the action of the potential of the first node Q1. Illustratively, the fourth switching sub-unit 211 may be turned on when the first node Q1 is at an active-level signal. The first voltage signal V1 corresponding to the first terminal of the fourth switching sub-unit 211 may be transmitted to the second terminal of the fourth switching sub-unit 211, that is, the second terminal of the fourth switching sub-unit 211 outputs the first voltage signal V1, that is, the output signal OUT output by the shift register is the first voltage signal V1. In addition, two terminals of the second energy storage sub-unit 212 are connected to the first node Q1 and the second terminal of the fourth switching sub-unit 211, respectively. The second energy storage sub-unit 212 may receive the input signal IN and/or the second clock signal CK2 for charging at least when the first clock signal CK1 is an active-level signal. The second energy storage sub-unit 212 may also directly discharge to the first node Q1 when the first clock signal CK1 switches from an active-level signal to an inactive-level signal, to maintain the potential of the first node Q1. That is, the potential of the first node Q1 is maintained through the discharging process of the second energy storage sub-unit 212, and the charging power of the second energy storage sub-unit 212 comes from the potential signal of the input signal IN and/or the second clock signal CK2. Illustratively, in a discharging process of the second energy storage sub-unit 212 shown in FIG. 5, the potential of the first node Q1 is clearly raised to achieve bootstrapping of the first node Q1, which can offset a drop of the potential of the first node Q1 generated by leakage current and maintain the potential of the first node Q1 to a potential level corresponding to the turn-on of the fourth switching sub-unit 211 so that the fourth switching sub-unit 211 is effectively turned on, and the output signal OUT corresponding to the shift register stably outputs the first voltage signal V1. In addition, illustratively, in a discharging process of the second energy storage sub-unit 212 shown in FIG. 7, the potential of the first node Q1 is clearly pulled down to achieve bootstrapping of the first node Q1, which can offset a rise of the potential of the first node Q1 generated by leakage current and maintain the potential of the first node Q1 to a potential level corresponding to the turn-on of the fourth switching sub-unit 211 so that the fourth switching sub-unit 211 is effectively turned on, and the output signal OUT corresponding to the shift register stably outputs the first voltage signal V1.

Similarly, the second output sub-unit 22 includes the fifth switching sub-unit 221 and the third energy storage sub-unit 222. A control terminal of the fifth switching sub-unit 221 is connected to the second node Q2, a first terminal of the fifth switching sub-unit 221 receives the second voltage signal V2, and a second terminal of the fifth switching sub-unit 221 may output the output signal OUT. In this manner, the fifth switching sub-unit 221 can be turned on or turned off under the action of the potential of the second node Q2. Illustratively, the fifth switching sub-unit 221 may be turned on when the second node Q2 is at an active-level signal. The second voltage signal V2 corresponding to the first terminal of the fifth switching sub-unit 221 may be transmitted to the second terminal of the fifth switching sub-unit 221, that is, the second terminal of the fifth switching sub-unit 221 outputs the second voltage signal V2, that is, the output signal OUT output by the shift register is the second voltage signal V2. In addition, two terminals of the third energy storage sub-unit 222 are connected to the second node Q2 and the second terminal of the fifth switching sub-unit 221, respectively. The third energy storage sub-unit 222 may receive the input signal IN, the second clock signal CK2, and/or the first clock signal CK1 for charging at least when the first clock signal CK1 is an inactive-level signal. The third energy storage sub-unit 222 may also directly discharge to the second node Q2 when the first clock signal CK1 switches from an inactive-level signal to an active-level signal, to maintain the potential of the second node Q2. That is, the potential of the second node Q2 is maintained through the discharging process of the third energy storage sub-unit 222, and the charging power of the third energy storage sub-unit 222 comes from the potential signal of the input signal IN, the second clock signal CK2, and/or the first clock signal CK1. Illustratively, in a discharging process of the third energy storage sub-unit 222 shown in FIG. 5, the potential of the second node Q2 is clearly raised to achieve bootstrapping of the second node Q2, which can offset a drop of the potential of the second node Q2 generated by leakage current and maintain the potential of the second node Q2 to a potential level corresponding to the turn-on of the fifth switching sub-unit 221 so that the fifth switching sub-unit 221 is effectively turned on, and the output signal OUT corresponding to the shift register stably outputs the second voltage signal V2. In addition, illustratively, in a discharging process of the third energy storage sub-unit 222 shown in FIG. 7, the potential of the second node Q2 is clearly pulled down to achieve bootstrapping of the second node Q2, which can offset a rise of the potential of the second node Q2 generated by leakage current and maintain the potential of the second node Q2 to a potential level corresponding to the turn-on of the fifth switching sub-unit 221 so that the fifth switching sub-unit 221 is effectively turned on, and the output signal OUT corresponding to the shift register stably outputs the second voltage signal V2.

It is also to be noted that the second terminal of the fourth switching sub-unit 211 and the second terminal of the fifth switching sub-unit 221 are connected to each other and output the output signal OUT, one of the potential of the first node Q1 and the potential of the second node Q2 is a logic high-level signal VGH, and the other of the potential of the first node Q1 and the potential of the second node Q2 is a logic low-level signal VGL. Therefore, when the potential of the first node Q1 is an active-level signal, the potential of the second node Q2 is correspondingly an inactive-level signal. In this case, the second terminal of the first output sub-unit 21 outputs the first voltage signal V1, and the second terminal of the second output sub-unit 22 does not output. That is, the output signal OUT output by the shift register is the first voltage signal V1. When the potential of the first node Q1 is an inactive-level signal, the potential of the second node Q2 is correspondingly an active-level signal. In this case, the second terminal of the second output sub-unit 22 outputs the second voltage signal V2, and the second terminal of the first output sub-unit 21 does not output. That is, the output signal OUT output by the shift register is the second voltage signal V2. That is, the potentials of the first node Q1 and the second node Q2 are appropriately set, and the on and off states of the fourth switching sub-unit 211 and the fifth switching sub-unit 221 are correspondingly regulated. In this manner, on the one hand, it can be ensured that the output signal OUT output by the shift register is free from interference between the fourth switching sub-unit 211 and the fifth switching sub-unit 221 to avoid abnormal output. On the other hand, it can be ensured that the output signal OUT output by the shift register can be switched between an active-level signal and an inactive-level signal. The driving timing of the input signal IN and the output signal OUT is not synchronized, thereby achieving a shift registration effect of delayed activation.

Optionally, with continued reference to FIG. 5, FIG. 9, FIG. 13, and FIG. 15, the fourth switching sub-unit 211 includes a fourth transistor T4, and the second energy storage sub-unit 212 includes a second capacitor C2. The fifth switching sub-unit 221 includes a fifth transistor T5, and the third energy storage sub-unit 222 includes a third capacitor C3. The fourth transistor T4 and the fifth transistor T5 have the same channel type. A first electrode of the fourth transistor T4 receives the first voltage signal V1, and a gate of the fourth transistor T4 and a first plate of the second capacitor C2 are both connected to the first node Q1. A first electrode of the fifth transistor T5 receives the second voltage signal V2, and a gate of the fifth transistor T5 and a first plate of the third capacitor C3 are both connected to the second node Q2. A second electrode of the fourth transistor T4, a second plate of the second capacitor C2, a second electrode of the fifth transistor T5, and a second plate of the third capacitor C3 are connected to each other and output the output signal OUT.

The fourth transistor T4 and the fifth transistor T5 have the same channel type. Optionally, the fourth transistor T4 and the fifth transistor T5 are both N-channel transistors. Then, active-level signals corresponding to the fourth transistor T4 and the fifth transistor T5 are both at a logic high level, and the fourth transistor T4 and the fifth transistor T5 may be turned on under the action of a logic high-level potential. Inactive-level signals corresponding to the fourth transistor T4 and the fifth transistor T5 are both at a logic low level, and the fourth transistor T4 and the fifth transistor T5 may be turned off under the action of a logic low-level potential. Illustratively, active-level signals of the first node Q1 and the second node Q2 may be a logic high-level signal VGH, inactive-level signals of the first node Q1 and the second node Q2 may be a logic low-level signal VGL, the first voltage signal V1 may be a logic high-level signal VGH, the second voltage signal V2 may be a logic low-level signal VGL, an active-level signal of the first clock signal CK1 may be a logic high-level signal VGH, and an inactive-level signal of the first clock signal CK1 may be a logic low-level signal VGL. Specifically, when the first clock signal CK1 is an active-level signal, that is, when the first clock signal CK1 is at a logic high level, the potential of the first node Q1 may also be at a logic high level. Then, the fourth transistor T4 is turned on, and the logic high-level signal VGH corresponding to the first voltage signal V1 may be transmitted to the second electrode of the fourth transistor T4 and output the output signal OUT. In this case, the output signal OUT is a logic high-level signal VGH, and the second capacitor C2 may be charged at the same time. In addition, when the first clock signal CK1 is an active-level signal, that is, when the first clock signal CK1 is at a logic high level, the potential of the second node Q2 may be at a logic low level. Then, the fifth transistor T5 is turned off. When the first clock signal CK1 switches from an active-level signal to an inactive-level signal, that is, when the first clock signal CK1 is converted from a logic high level to a logic low level, the first node Q1 is floating, and the potential of the first node Q1 maintains the state of the previous phase, that is, the potential of the first node Q1 is still at a logic high level. In addition, the second capacitor C2 discharges to the first node Q1 to raise the potential of the first node Q1 to a logic high level, thereby keeping the fourth transistor T4 turned on and avoiding the situation in which the potential of the first node Q1 drops due to leakage current and the on state of the fourth transistor T4 cannot be guaranteed.

In addition, when the first clock signal CK1 is an inactive-level signal, that is, when the first clock signal CK1 is at a logic low level, the potential of the second node Q2 may be at a logic low level. Then, the fifth transistor T5 is turned off, and the third capacitor C3 may be charged at the same time. In addition, when the first clock signal CK1 is an inactive-level signal, that is, when the first clock signal CK1 is at a logic low level, the potential of the first node Q1 may be at a logic high level. Then, the fourth transistor T4 is turned on. When the first clock signal CK1 switches from an inactive-level signal to an active-level signal, that is, when the first clock signal CK1 is converted from a logic low level to a logic high level, the second node Q2 is floating, and the potential of the second node Q2 maintains the state of the previous phase, that is, the potential of the second node Q2 is still at a logic low level. In addition, the third capacitor C3 discharges to the second node Q2 to maintain the potential of the second node Q2, thereby keeping the fifth transistor T5 turned off and avoiding the situation in which the potential of the second node Q2 changes due to leakage current and the off state of the fifth transistor T5 cannot be guaranteed.

In another specific embodiment, the fourth transistor T4 and the fifth transistor T5 have the same channel type. Optionally, with continued reference to FIG. 7, FIG. 11, FIG. 14, and FIG. 16, the fourth transistor T4 and the fifth transistor T5 are both P-channel transistors, the first voltage signal V1 is a logic low-level signal VGL, and the second voltage signal V2 is a logic high-level signal VGH. Related content may refer to the preceding embodiments and is not repeated in this embodiment.

Optionally, with continued reference to FIG. 5, FIG. 7, FIG. 9, FIG. 11, FIG. 13 to FIG. 16, the control unit 10 includes a sixth switching sub-unit 11, a seventh switching sub-unit 12, an eighth switching sub-unit 13, a ninth switching sub-unit 14, a tenth switching sub-unit 15, and a fourth energy storage sub-unit 16. A first terminal of the sixth switching sub-unit 11 and a control terminal of the seventh switching sub-unit 12 are connected and receive the input signal IN. A second terminal of the sixth switching sub-unit 11, a first terminal of the eighth switching sub-unit 13, and a control terminal of the ninth switching sub-unit 14 are connected to a third node Q3. A control terminal of the sixth switching sub-unit 11 receives the first clock signal CK1. A first terminal of the seventh switching sub-unit 12 receives the second voltage signal V2. A second terminal of the seventh switching sub-unit 12, a control terminal of the tenth switching sub-unit 15, and a first terminal of the fourth energy storage sub-unit 16 are connected to a fifth node Q5. A second terminal of the eighth switching sub-unit 13 is connected to the first node Q1, and a control terminal of the eighth switching sub-unit 13 receives the first voltage signal V1. A first terminal of the ninth switching sub-unit 14 receives the second voltage signal V2, and a second terminal of the ninth switching sub-unit 14 and a first terminal of the tenth switching sub-unit 15 are connected to the second node Q2. A second terminal of the tenth switching sub-unit 15 is connected to a second terminal of the fourth energy storage sub-unit 16. The sixth switching sub-unit 11 is configured to be turned on when the first clock signal CK1 is an active-level signal. The seventh switching sub-unit 12 is configured to be turned on when the input signal IN is an active-level signal. The fourth energy storage sub-unit 16 is configured to receive the second voltage signal V2 for charging when the input signal IN is an active-level signal, and to discharge to the fifth node Q5 when the input signal IN switches from an active-level signal to an inactive-level signal, to maintain the potential of the fifth node Q5.

Specifically, the control terminal of the sixth switching sub-unit 11 receives the first clock signal CK1, the first terminal of the sixth switching sub-unit 11 receives the input signal IN, and the second terminal of the sixth switching sub-unit 11 is connected to the third node Q3. In this manner, the sixth switching sub-unit 11 can be turned on or turned off under the action of the potential of the first clock signal CK1. Illustratively, the sixth switching sub-unit 11 may be turned on when the first clock signal CK1 is an active-level signal. The input signal IN corresponding to the first terminal of the sixth switching sub-unit 11 may be transmitted to the third node Q3. In addition, the control terminal of the eighth switching sub-unit 13 receives the first voltage signal V1, the first terminal of the eighth switching sub-unit 13 is connected to the third node Q3, and the second terminal of the eighth switching sub-unit 13 is connected to the first node Q1. In this manner, the eighth switching sub-unit 13 can be turned on or turned off under the action of the potential of the first voltage signal V1. Illustratively, the eighth switching sub-unit 13 may be turned on when the first voltage signal V1 is an active-level signal. The eighth switching sub-unit 13 may be understood as being constantly on. The input signal IN corresponding to the first terminal of the sixth switching sub-unit 11 may be transmitted to the first node Q1 via the third node Q3 and the eighth switching sub-unit 13, so as to subsequently control the turn-on or turn-off of the first output sub-unit 21 according to the potential of the input signal IN and further control the output of the output signal OUT of the shift register. In addition, the control terminal of the ninth switching sub-unit 14 is connected to the third node Q3, the first terminal of the ninth switching sub-unit 14 receives the second voltage signal V2, and the second terminal of the ninth switching sub-unit 14 is connected to the second node Q2. In this manner, the ninth switching sub-unit 14 can be turned on or turned off under the action of the potential of the third node Q3. Illustratively, the ninth switching sub-unit 14 may be turned on when the third node Q3 is at an active-level signal. The input signal IN corresponding to the first terminal of the sixth switching sub-unit 11 may be transmitted to the second node Q2 via the third node Q3 and the ninth switching sub-unit 14, so as to subsequently control the turn-on or turn-off of the second output sub-unit 22 according to the potential of the input signal IN and further control the output of the output signal OUT of the shift register.

The control terminal of the seventh switching sub-unit 12 receives the input signal IN, the first terminal of the seventh switching sub-unit 12 receives the second voltage signal V2, and the second terminal of the seventh switching sub-unit 12 is connected to the fifth node Q5. In this manner, the seventh switching sub-unit 12 can be turned on or turned off under the action of the potential of the input signal IN. Illustratively, the seventh switching sub-unit 12 may be turned on when the input signal IN is an active-level signal. The second voltage signal V2 corresponding to the first terminal of the seventh switching sub-unit 12 may be transmitted to the fifth node Q5. In addition, the control terminal of the tenth switching sub-unit 15 is connected to the fifth node Q5, the first terminal of the tenth switching sub-unit 15 is connected to the second node Q2, and two terminals of the fourth energy storage sub-unit 16 are connected to the fifth node Q5 and the second terminal of the tenth switching sub-unit 15, respectively. In this manner, the tenth switching sub-unit 15 can be turned on or turned off under the action of the potential of the fifth node Q5. Illustratively, the tenth switching sub-unit 15 may be turned on when the fifth node Q5 is at an active-level signal. A capacitor storage signal corresponding to the second terminal of the tenth switching sub-unit 15 may be transmitted to the second node Q2, so as to subsequently control the turn-on or turn-off of the second output sub-unit 22 according to the potential of the input signal IN and further control the output of the output signal OUT of the shift register.

It can be understood that when the input signal IN is an active-level signal, the seventh switching sub-unit 12 is turned on, and the second voltage signal V2 corresponding to the first terminal of the seventh switching sub-unit 12 may be transmitted to one terminal of the fourth energy storage sub-unit 16. Then, the fourth energy storage sub-unit 16 may receive the second voltage signal V2 for charging. When the input signal IN switches from an active-level signal to an inactive-level signal, the seventh switching sub-unit 12 is turned off, and the second voltage signal V2 corresponding to the first terminal of the seventh switching sub-unit 12 cannot be transmitted to one terminal of the fourth energy storage sub-unit 16. Then, the fourth energy storage sub-unit 16 may maintain the state of the previous phase. The fourth energy storage sub-unit 16 discharges to the fifth node Q5 to maintain the potential of the fifth node Q5. In addition, a connection node between the second terminal of the seventh switching sub-unit 12 and one terminal of the fourth energy storage sub-unit 16 is the fifth node Q5. That is, the fourth energy storage sub-unit 16 may receive the second voltage signal V2 for charging when the input signal IN is an active-level signal. The fourth energy storage sub-unit 16 may also discharge to the fifth node Q5 when the input signal IN switches from an active-level signal to an inactive-level signal, to maintain the potential of the fifth node Q5. That is, the potential of the fifth node Q5 is maintained through the discharging process of the fourth energy storage sub-unit 16, and the charging power of the fourth energy storage sub-unit 16 comes from the potential signal of the second voltage signal V2. Furthermore, the potential of the second node Q2 may be correspondingly maintained through the potential of the fifth node Q5 so that the second output sub-unit 22 is kept turned off or kept turned on, thereby controlling the output of the output signal OUT of the shift register.

Optionally, with continued reference to FIG. 5, FIG. 9, FIG. 13, and FIG. 15, the sixth switching sub-unit 11 includes a sixth transistor T6, the seventh switching sub-unit 12 includes a seventh transistor T7, the eighth switching sub-unit 13 includes an eighth transistor T8, the ninth switching sub-unit 14 includes a ninth transistor T9, the tenth switching sub-unit 15 includes a tenth transistor T10, and the fourth energy storage sub-unit 16 includes a fourth capacitor C4. The sixth transistor T6, the seventh transistor T7, the eighth transistor T8, the ninth transistor T9, and the tenth transistor T10 have the same channel type. A first electrode of the sixth transistor T6 and a gate of the seventh transistor T7 are connected and receive the input signal IN. A second electrode of the sixth transistor T6, a first electrode of the eighth transistor T8, and a gate of the ninth transistor T9 are connected to the third node Q3. A gate of the sixth transistor T6 receives the first clock signal CK1. A first electrode of the seventh transistor T7 receives the second voltage signal V2. A second electrode of the seventh transistor T7, a gate of the tenth transistor T10, and a first plate of the fourth capacitor C4 are connected to the fifth node Q5. A second electrode of the eighth transistor T8 is connected to the first node Q1, and a gate of the eighth transistor T8 receives the first voltage signal V1. A first electrode of the ninth transistor T9 receives the second voltage signal V2. A second electrode of the ninth transistor T9 and a first electrode of the tenth transistor T10 are connected to the second node Q2. A second electrode of the tenth transistor T10 is connected to a second plate of the fourth capacitor C4.

The sixth transistor T6, the seventh transistor T7, the eighth transistor T8, the ninth transistor T9, and the tenth transistor T10 have the same channel type. Optionally, the sixth transistor T6, the seventh transistor T7, the eighth transistor T8, the ninth transistor T9, and the tenth transistor T10 are all N-channel transistors. Then, active-level signals corresponding to the sixth transistor T6, the seventh transistor T7, the eighth transistor T8, the ninth transistor T9, and the tenth transistor T10 are all at a logic high level, and the sixth transistor T6, the seventh transistor T7, the eighth transistor T8, the ninth transistor T9, and the tenth transistor T10 may be turned on under the action of a logic high-level potential. Inactive-level signals corresponding to the sixth transistor T6, the seventh transistor T7, the eighth transistor T8, the ninth transistor T9, and the tenth transistor T10 are all at a logic low level, and the sixth transistor T6, the seventh transistor T7, the eighth transistor T8, the ninth transistor T9, and the tenth transistor T10 may be turned off under the action of a logic low-level potential. Illustratively, active-level signals of the first node Q1, the second node Q2, the third node Q3, and the fifth node Q5 may be a logic high-level signal VGH, inactive-level signals of the first node Q1, the second node Q2, the third node Q3, and the fifth node Q5 may be a logic low-level signal VGL, the first voltage signal V1 may be a logic high-level signal VGH, the second voltage signal V2 may be a logic low-level signal VGL, an active-level signal of the first clock signal CK1 may be a logic high-level signal VGH, an inactive-level signal of the first clock signal CK1 may be a logic low-level signal VGL, an active-level signal of the input signal IN may be a logic high-level signal VGH, and an inactive-level signal of the input signal IN may be a logic low-level signal VGL. Specifically, when the first clock signal CK1 is an active-level signal and the input signal IN is an active-level signal, that is, when the first clock signal CK1 is at a logic high level and the input signal IN is at a logic high level, the sixth transistor T6 is turned on, the potential of the third node Q3 is at a logic high level, the eighth transistor T8 is constantly turned on, and the potential of the first node Q1 is also at a logic high level. Then, the first output sub-unit 21 is turned on, and the second terminal of the first output sub-unit 21 outputs the first voltage signal V1, that is, the output signal OUT output by the shift register is the first voltage signal V1, that is, the shift register outputs a logic high-level signal VGH. At the same time, when the input signal IN is an active-level signal, that is, when the input signal IN is at a logic high level, the seventh transistor T7 is turned on, the potential of the fifth node Q5 is at a logic low level, and the fourth capacitor C4 receives the second voltage signal V2 for charging. In addition, when the input signal IN switches from an active-level signal to an inactive-level signal, that is, when the input signal IN is converted from a logic high level to a logic low level, the seventh transistor T7 is turned off, the fifth node Q5 is floating, and the potential of the fifth node Q5 maintains the state of the previous phase, that is, the potential of the fifth node Q5 is still at a logic low level. In addition, the fourth capacitor C4 discharges to the fifth node Q5 to maintain the potential of the fifth node Q5, thereby keeping the seventh transistor T7 stably turned off. Afterwards, the potential of the second node Q2 may be regulated according to the turn-on or turn-off of the ninth transistor T9. When the potential of the first node Q1 is at a logic high level, the ninth transistor T9 is turned on. Then, the potential of the second node Q2 is a logic low-level signal VGL corresponding to the second voltage signal V2. Then, the second output sub-unit 22 is turned off, and the second terminal of the second output sub-unit 22 does not output the second voltage signal V2. The output of the shift register may be determined according to the on or off state of the first output sub-unit 21.

In still another specific embodiment, the sixth transistor T6, the seventh transistor T7, the eighth transistor T8, the ninth transistor T9, and the tenth transistor T10 have the same channel type. Optionally, with continued reference to FIG. 7, FIG. 11, FIG. 14, and FIG. 16, the sixth transistor T6, the seventh transistor T7, the eighth transistor T8, the ninth transistor T9, and the tenth transistor T10 are all P-channel transistors. Related content may refer to the preceding embodiments and is not repeated in this embodiment.

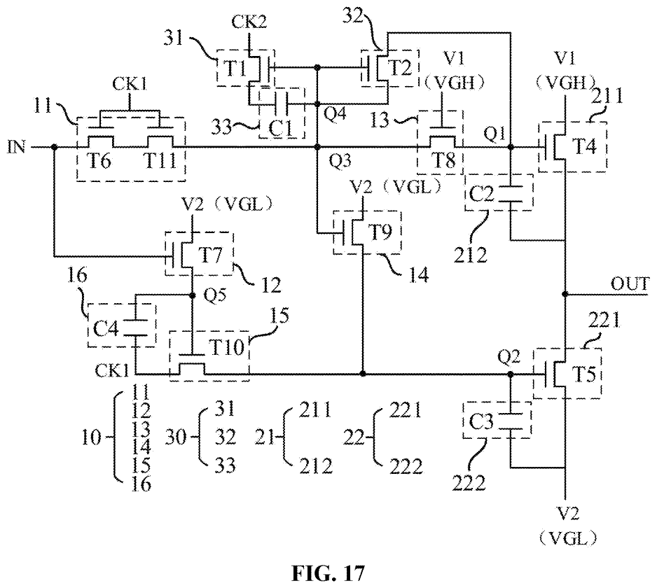

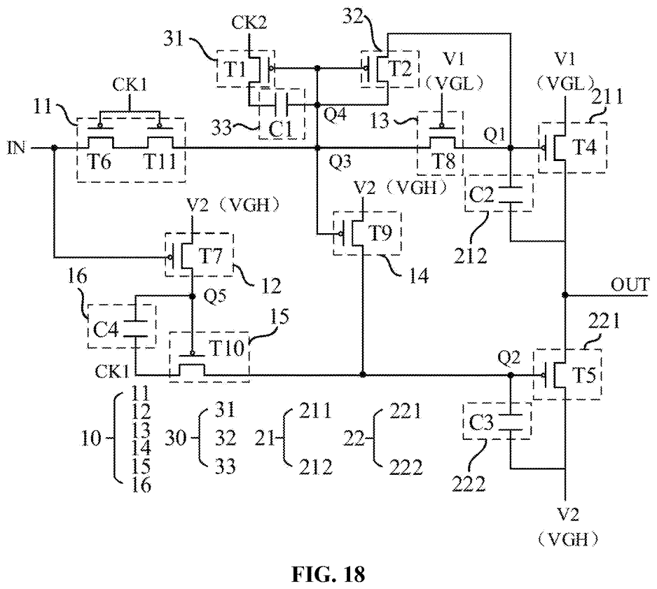

Optionally, FIG. 17 is a schematic diagram illustrating another specific structure of the shift register in the driver circuit shown in FIG. 4, and FIG. 18 is a schematic diagram illustrating another specific structure of the shift register in the driver circuit shown in FIG. 4. As shown in FIG. 17 and FIG. 18, the sixth switching sub-unit 11 also includes an eleventh transistor T11, and the eleventh transistor T11 has the same channel type as the sixth transistor T6. A first electrode of the eleventh transistor T11 is connected to the second electrode of the sixth transistor T6, a second electrode of the eleventh transistor T11 is connected to the third node Q3, and a gate of the eleventh transistor T11 receives the first clock signal CK1.

Specifically, the sixth switching sub-unit 11 includes the sixth transistor T6 and the eleventh transistor T11. The first electrode of the sixth transistor T6 receives the input signal IN, and the second electrode of the sixth transistor T6 is connected to the first electrode of the eleventh transistor T11. The second electrode of the eleventh transistor T11 is connected to the third node Q3. The gate of the sixth transistor T6 and the gate of the eleventh transistor T11 are connected and receive the first clock signal CK1. That is, the sixth transistor T6 and the eleventh transistor T11 form a dual-gate transistor, which may further block a leakage path formed from the first node Q1 through the third node Q3, the eleventh transistor T11, and the sixth transistor T6. This avoids the situation in which such leakage current causes the potential of the first node Q1 to fail to be maintained, thereby preventing abnormalities in the output of the first output sub-unit 21 and the output signal OUT. In addition, the eleventh transistor T11 has the same channel type as the sixth transistor T6. Illustratively, the eleventh transistor T11 and the sixth transistor T6 shown in FIG. 17 are both N-channel transistors, and the eleventh transistor T11 and the sixth transistor T6 shown in FIG. 18 are both P-channel transistors.

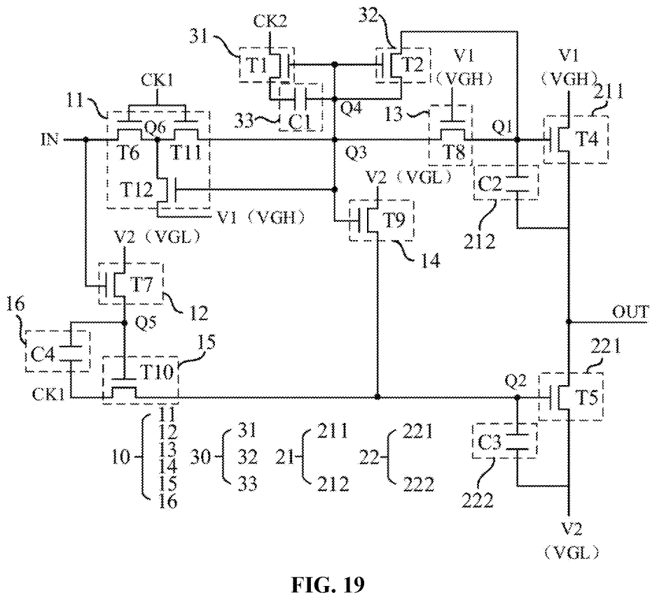

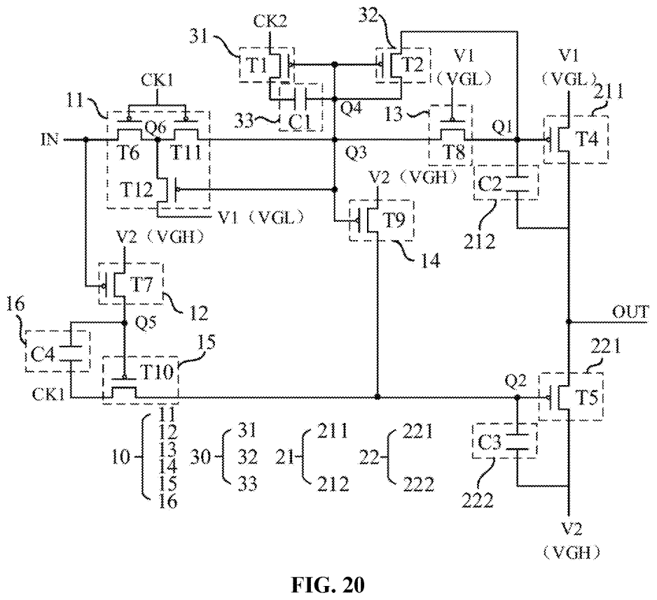

Optionally, FIG. 19 is a schematic diagram illustrating another specific structure of the shift register in the driver circuit shown in FIG. 4, and FIG. 20 is a schematic diagram illustrating another specific structure of the shift register in the driver circuit shown in FIG. 4. As shown in FIG. 19 and FIG. 20, the sixth switching sub-unit 11 also includes a twelfth transistor T12, and the twelfth transistor T12 has the same channel type as the sixth transistor T6. The second electrode of the sixth transistor T6 and the first electrode of the eleventh transistor T11 are connected to a sixth node Q6, and a first electrode of the twelfth transistor T12 is connected to the sixth node Q6. A second electrode of the twelfth transistor T12 receives the first voltage signal V1, and a gate of the twelfth transistor T12 is connected to the third node Q3.

Specifically, the sixth switching sub-unit 11 includes the sixth transistor T6, the eleventh transistor T11, and the twelfth transistor T12. The second electrode of the sixth transistor T6, the first electrode of the eleventh transistor T11, and the first electrode of the twelfth transistor T12 are connected to each other and connected to the sixth node Q6. The second electrode of the twelfth transistor T12 receives the first voltage signal V1, and the gate of the twelfth transistor T12 is connected to the third node Q3. In this manner, the twelfth transistor T12 can be turned on or turned off under the action of the potential of the third node Q3. It can be understood that if the voltage difference between the third node Q3 and the sixth node Q6 is excessively large, a leakage path is easily formed between the third node Q3 and the sixth node Q6. In this case, the arrangement of the twelfth transistor T12 may reduce the voltage difference between the third node Q3 and the sixth node Q6 after the eleventh transistor T11 is turned off, thereby further preventing the first node Q1 from forming a leakage path through the third node Q3, the eleventh transistor T11, and the sixth transistor T6, thereby preventing abnormalities in the output of the first output sub-unit 21 and the output signal OUT. In addition, the twelfth transistor T12 has the same channel type as the sixth transistor T6. Illustratively, the sixth transistor T6, the eleventh transistor T11, and the twelfth transistor T12 shown in FIG. 19 are all N-channel transistors, the first voltage signal V1 shown in FIG. 19 is a logic high-level signal VGH, and active-level signals of the first node Q1 and the third node Q3 shown in FIG. 19 are also at a logic high level. The sixth transistor T6, the eleventh transistor T11, and the twelfth transistor T12 shown in FIG. 20 are all P-channel transistors, the first voltage signal V1 shown in FIG. 20 is a logic low-level signal VGL, and active-level signals of the first node Q1 and the third node Q3 shown in FIG. 20 are also at a logic low level.

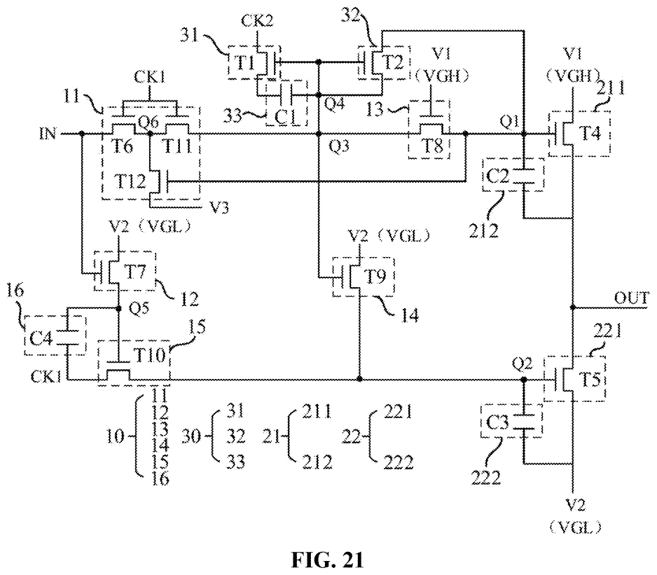

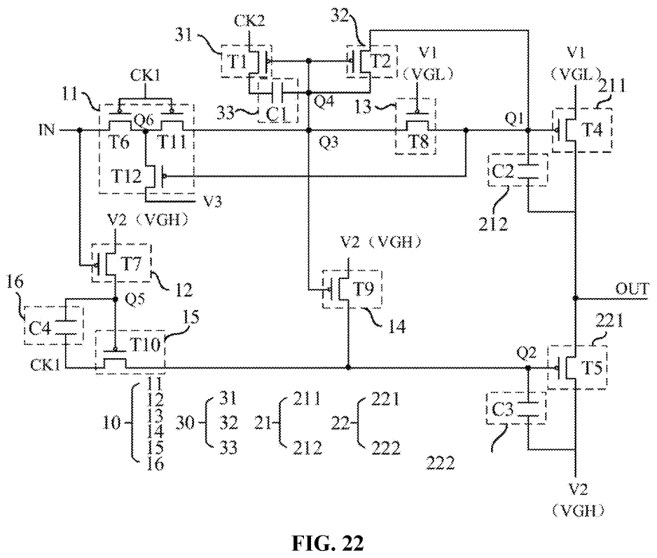

Alternatively or optionally, FIG. 21 is a schematic diagram illustrating another specific structure of the shift register in the driver circuit shown in FIG. 4, and FIG. 22 is a schematic diagram illustrating another specific structure of the shift register in the driver circuit shown in FIG. 4. As shown in FIG. 21 and FIG. 22, the sixth switching sub-unit 11 also includes a twelfth transistor T12, and the twelfth transistor T12 has the same channel type as the sixth transistor T6. The second electrode of the sixth transistor T6 and the first electrode of the eleventh transistor T11 are connected to a sixth node Q6, and a first electrode of the twelfth transistor T12 is connected to the sixth node Q6. A second electrode of the twelfth transistor T12 receives a third voltage signal V3, and a gate of the twelfth transistor T12 is connected to the first node Q1.

Specifically, the sixth switching sub-unit 11 includes the sixth transistor T6, the eleventh transistor T11, and the twelfth transistor T12. The second electrode of the sixth transistor T6, the first electrode of the eleventh transistor T11, and the first electrode of the twelfth transistor T12 are connected to each other and connected to the sixth node Q6. The second electrode of the twelfth transistor T12 receives the third voltage signal V3, and the gate of the twelfth transistor T12 is connected to the first node Q1. In this manner, the twelfth transistor T12 can be turned on or turned off under the action of the potential of the first node Q1. It can be understood that if the voltage difference between the first node Q1 and the sixth node Q6 is excessively large, a leakage path is easily formed between the first node Q1 and the sixth node Q6. In this case, the arrangement of the twelfth transistor T12 may reduce the voltage difference between the first node Q1 and the sixth node Q6 after the eleventh transistor T11 is turned off, thereby further preventing the first node Q1 from forming a leakage path through the third node Q3, the eleventh transistor T11, and the sixth transistor T6, thereby preventing abnormalities in the output of the first output sub-unit 21 and the output signal OUT.

In addition, the twelfth transistor T12 has the same channel type as the sixth transistor T6. Illustratively, the sixth transistor T6, the eleventh transistor T11, and the twelfth transistor T12 shown in FIG. 21 are all N-channel transistors, the third voltage signal V3 shown in FIG. 21 may be understood as HVGH, the potential of the third voltage signal V3 shown in FIG. 21 is greater than the potential of the first voltage signal V1 shown in FIG. 19, and active-level signals of the first node Q1 and the third node Q3 shown in FIG. 21 are at a logic high level. In some embodiments, the potential of the third voltage signal V3 is higher so that the voltages of both the sixth node Q6 and the first node Q1 are higher than the voltage of the control terminal of the eleventh transistor T11. According to the turn-on condition, that is, Vg>Vs, of an N-channel transistor, it can be known that the eleventh transistor T11 will be completely turned off, thereby better maintaining the high-voltage state of the first node Q1 and further keeping the output of the first output sub-unit 21 corresponding to the first node Q1. That is, the output signal OUT output by the shift register is a potential signal corresponding to the first voltage signal V1. The stable output of the output signal OUT of the shift register may also improve display quality of the display panel. In addition, the twelfth transistor T12 has the same channel type as the sixth transistor T6. Illustratively, the sixth transistor T6, the eleventh transistor T11, and the twelfth transistor T12 shown in FIG. 22 are all P-channel transistors, the third voltage signal V3 shown in FIG. 22 may be understood as LVGL, the potential of the third voltage signal V3 shown in FIG. 22 is smaller than the potential of the first voltage signal V1 shown in FIG. 20, and active-level signals of the first node Q1 and the third node Q3 shown in FIG. 22 are at a logic low level. In some embodiments, the potential of the third voltage signal V3 is lower so that the voltages of both the sixth node Q6 and the first node Q1 are lower than the voltage of the control terminal of the eleventh transistor T11. According to the turn-on condition, that is, Vg<Vs, of a P-channel transistor, it can be known that the eleventh transistor T11 will be completely turned off, thereby better maintaining the low-voltage state of the first node Q1 and further keeping the output of the first output sub-unit 21 corresponding to the first node Q1. That is, the output signal OUT output by the shift register is a potential signal corresponding to the first voltage signal V1. The stable output of the output signal OUT of the shift register may also improve display quality of the display panel.

Based on the detailed description of the specific structures of the preceding control unit 10, the output unit 20, and the node voltage regulation unit 30, with continued reference to FIG. 5 and FIG. 6, a specific driving process of the driver circuit 100 is described with an example. In phase t1, the first clock signal CK1 is at a logic high level. In this case, the sixth transistor T6 is turned on, a logic high level corresponding to the input signal IN may be transmitted to the third node Q3, and the eighth transistor T8 is constantly turned on. Therefore, the potentials of the third node Q3 and the first node Q1 are both at a logic high level. In this case, the fourth transistor T4 is turned on, and a logic high-level signal VGH corresponding to the first terminal of the fourth transistor T4 may be transmitted to the second terminal of the fourth transistor T4, that is, the output signal OUT output by the shift register is correspondingly at a logic high level. At the same time, the potential of the third node Q3 is at a logic high level, and both the first transistor T1 and the second transistor T2 are turned on. The second clock signal CK2 corresponding to the first terminal of the first transistor T1 may be transmitted to the second terminal of the first transistor T1 and causes the first capacitor C1 to be charged. In addition, the input signal IN is at a logic high level. In this case, the seventh transistor T7 is turned on, and a logic low-level signal VGL corresponding to the first terminal of the seventh transistor T7 may be transmitted to the fifth node Q5. In this case, the tenth transistor T10 is turned off. In addition, the potential of the third node Q3 is at a logic high level. In this case, the ninth transistor T9 is turned on, and a logic low-level signal VGL corresponding to the first terminal of the ninth transistor T9 may be transmitted to the second node Q2. In this case, the fifth transistor T5 is turned off.

In an s2 phase, when the first clock signal CK1 is at a logic low level, the sixth transistor T6 is turned off, and the logic high level corresponding to the input signal IN cannot be transmitted to the third node Q3. At the same time, the first capacitor C1 stabilizes a voltage to the potential of the previous phase. The first capacitor C1 may keep the voltage difference across the first capacitor C1 unchanged so that the potential of the third node Q3 is still maintained at a logic high level, and the second transistor T2 remains turned on. Electric energy stored in the first capacitor C1 may be discharged to the first node Q1 via the second transistor T2 to raise the potential of the first node Q1. In this case, the fourth transistor T4 continues to be turned on, and the logic high-level signal VGH corresponding to the first terminal of the fourth transistor T4 may be transmitted to the second terminal of the fourth transistor T4, that is, the output signal OUT output by the shift register is still correspondingly at a logic high level, thereby ensuring the stable output of the output signal OUT of the shift register. In addition, the input signal IN is at a logic high level. In this case, the seventh transistor T7 is turned on, and a logic low-level signal VGL corresponding to the first terminal of the seventh transistor T7 may be transmitted to the fifth node Q5. In this case, the tenth transistor T10 is turned off. In addition, the eighth transistor T8 is constantly turned on, and the potentials of the third node Q3 and the first node Q1 are both maintained at a logic high level. In this case, the ninth transistor T9 is turned on, and the logic low-level signal VGL corresponding to the first terminal of the ninth transistor T9 may be transmitted to the second node Q2. In this case, the fifth transistor T5 is turned off. The fifth transistor T5 does not output at this time and does not affect the logic high-level output of the output signal OUT of the shift register. In the s2 phase, when the first clock signal CK1 is at a logic high level, the sixth transistor T6 is turned on, the logic high level corresponding to the input signal IN may be transmitted to the third node Q3, and the eighth transistor T8 is constantly turned on. Therefore, the potentials of the third node Q3 and the first node Q1 are both at a logic high level. The second capacitor C2 may stabilize a voltage to the potential of the previous phase. The second capacitor C2 discharges to the first node Q1 to maintain the potential of the first node Q1. In this case, the fourth transistor T4 is turned on, and the logic high-level signal VGH corresponding to the first terminal of the fourth transistor T4 may be transmitted to the second terminal of the fourth transistor T4, that is, the output signal OUT of the shift register continues to correspond to a logic high-level output.

In an s3 phase, when the first clock signal CK1 is at a logic low level, the sixth transistor T6 is turned off, and the logic high level corresponding to the input signal IN cannot be transmitted to the third node Q3. At the same time, the first capacitor C1 stabilizes a voltage to the potential of the previous phase so that the potential of the third node Q3 is still maintained at a logic high level, and the second transistor T2 remains turned on. Electric energy stored in the first capacitor C1 may be discharged to the first node Q1 via the second transistor T2 to raise the potential of the first node Q1. In this case, the fourth transistor T4 continues to be turned on, and the logic high-level signal VGH corresponding to the first terminal of the fourth transistor T4 may be transmitted to the second terminal of the fourth transistor T4, that is, the output signal OUT output by the shift register is still correspondingly at a logic high level. In addition, the input signal IN is at a logic low level. In this case, the seventh transistor T7 is turned off, and the logic low-level signal VGL corresponding to the first terminal of the seventh transistor T7 cannot be transmitted to the fifth node Q5. The fourth capacitor C4 may be charged according to the first clock signal CK1 and discharge to the fifth node Q5. However, since the fourth capacitor C4 stabilizes the voltage to the potential of the previous phase, the tenth transistor T10 remains turned off no matter whether the first clock signal CK1 is at a logic high level or a logic low level. In addition, the eighth transistor T8 is constantly turned on, and the potentials of the third node Q3 and the first node Q1 are both maintained at a logic high level. In this case, the ninth transistor T9 is turned on, and the logic low-level signal VGL corresponding to the first terminal of the ninth transistor T9 may be transmitted to the second node Q2. At the same time, the third capacitor C3 stabilizes the voltage to the potential of the previous phase so that the potential of the second node Q2 is still maintained at a logic low level. In this case, the fifth transistor T5 is turned off.

In an s4 phase, when the first clock signal CK1 is at a logic high level, the sixth transistor T6 is turned on, and a logic low level corresponding to the input signal IN may be transmitted to the third node Q3. The fifth transistor T5 is constantly turned on so that the potentials of the third node Q3 and the first node Q1 are both at a logic low level. In this case, the sixth transistor T6 is turned off. In addition, the input signal IN is at a logic low level. In this case, the seventh transistor T7 is turned off, and the logic low-level signal VGL corresponding to the first terminal of the seventh transistor T7 cannot be transmitted to the fifth node Q5. However, at this time, the fourth capacitor C4 stabilizes the voltage to the potential of the previous phase, that is, the potential of the first clock signal CK1. Therefore, the potential of the fifth node Q5 is at a logic high level corresponding to the first clock signal CK1. In this case, the tenth transistor T10 is turned on. The logic high level corresponding to the first clock signal CK1 may be transmitted to the second node Q2. In this case, the fifth transistor T5 is turned on, and the logic low-level signal VGL corresponding to the first terminal of the fifth transistor T5 may be transmitted to the second terminal of the fifth transistor T5, that is, the output signal OUT output by the shift register is correspondingly at a logic low level. In the s4 phase, when the first clock signal CK1 is at a logic low level, the sixth transistor T6 is turned off, and the logic low level corresponding to the input signal IN cannot be transmitted to the third node Q3. At the same time, the second capacitor C2 stabilizes the voltage to the potential of the previous phase so that the potential of the first node Q1 is still maintained at a logic low level. In this case, the sixth transistor T6 continues to be turned off. In addition, the input signal IN is at a logic low level. In this case, the seventh transistor T7 is turned off, and the logic low-level signal VGL corresponding to the first terminal of the seventh transistor T7 cannot be transmitted to the fifth node Q5. However, at this time, the first capacitor C1 still stabilizes the voltage to the potential of the previous phase, that is, the potential of the first clock signal CK1. Therefore, the potential of the fifth node Q5 is at a logic low level corresponding to the first clock signal CK1. In this case, the tenth transistor T10 is turned off. In addition, at this time, the third capacitor C3 stabilizes the voltage to the potential of the previous phase. The third capacitor C3 discharges to the second node Q2 to maintain the potential of the second node Q2 so that the potential of the second node Q2 is still maintained at a logic high level. In this case, the fifth transistor T5 continues to be turned on, and the logic low-level signal VGL corresponding to the first terminal of the fifth transistor T5 may be transmitted to the second terminal of the fifth transistor T5, that is, the output signal OUT output by the shift register is correspondingly at a logic low level.

Similarly, with continued reference to FIG. 7 and FIG. 8, another specific driving process of the driver circuit 100 is described with an example. In phase t1, the first clock signal CK1 is at a logic low level. In this case, the sixth transistor T6 is turned on, a logic low level corresponding to the input signal IN may be transmitted to the third node Q3, and the eighth transistor T8 is constantly turned on. Therefore, the potentials of the third node Q3 and the first node Q1 are both at a logic low level. In this case, the fourth transistor T4 is turned on, and a logic low-level signal VGL corresponding to the first terminal of the fourth transistor T4 may be transmitted to the second terminal of the fourth transistor T4, that is, the output signal OUT output by the shift register is correspondingly at a logic low level. At the same time, the potential of the third node Q3 is at a logic low level, and both the first transistor T1 and the second transistor T2 are turned on. The second clock signal CK2 corresponding to the first terminal of the first transistor T1 may be transmitted to the second terminal of the first transistor T1 and causes the first capacitor C1 to be charged. In addition, the input signal IN is at a logic low level. In this case, the seventh transistor T7 is turned on, and a logic high-level signal VGH corresponding to the first terminal of the seventh transistor T7 may be transmitted to the fifth node Q5. In this case, the tenth transistor T10 is turned off. In addition, the potential of the third node Q3 is at a logic low level. In this case, the ninth transistor T9 is turned on, and a logic high-level signal VGH corresponding to the first terminal of the ninth transistor T9 may be transmitted to the second node Q2. In this case, the fifth transistor T5 is turned off.

In an s2 phase, when the first clock signal CK1 is at a logic high level, the sixth transistor T6 is turned off, and the logic low level corresponding to the input signal IN cannot be transmitted to the third node Q3. At the same time, the first capacitor C1 stabilizes a voltage to the potential of the previous phase. The first capacitor C1 may keep the voltage difference across the first capacitor C1 unchanged so that the potential of the third node Q3 is still maintained at a logic low level, and the second transistor T2 remains turned on. Electric energy stored in the first capacitor C1 may be discharged to the first node Q1 via the second transistor T2 to pull down the potential of the first node Q1. In this case, the fourth transistor T4 continues to be turned on, and the logic low-level signal VGL corresponding to the first terminal of the fourth transistor T4 may be transmitted to the second terminal of the fourth transistor T4, that is, the output signal OUT output by the shift register is still correspondingly at a logic low level, thereby ensuring the stable output of the output signal OUT of the shift register. In addition, the input signal IN is at a logic low level. In this case, the seventh transistor T7 is turned on, and a logic high-level signal VGH corresponding to the first terminal of the seventh transistor T7 may be transmitted to the fifth node Q5. In this case, the tenth transistor T10 is turned off. In addition, the eighth transistor T8 is constantly turned on, and the potentials of the third node Q3 and the first node Q1 are both maintained at a logic low level. In this case, the ninth transistor T9 is turned on, and the logic high-level signal VGH corresponding to the first terminal of the ninth transistor T9 may be transmitted to the second node Q2. In this case, the fifth transistor T5 is turned off. The fifth transistor T5 does not output at this time and does not affect the logic low-level output of the output signal OUT of the shift register. In the s2 phase, when the first clock signal CK1 is at a logic low level, the sixth transistor T6 is turned on, the logic low level corresponding to the input signal IN may be transmitted to the third node Q3, and the eighth transistor T8 is constantly turned on. Therefore, the potentials of the third node Q3 and the first node Q1 are both at a logic low level. The second capacitor C2 may stabilize a voltage to the potential of the previous phase. The second capacitor C2 discharges to the first node Q1 to maintain the potential of the first node Q1. In this case, the fourth transistor T4 is turned on, and the logic low-level signal VGL corresponding to the first terminal of the fourth transistor T4 may be transmitted to the second terminal of the fourth transistor T4, that is, the output signal OUT of the shift register continues to correspond to a logic low-level output.

In an s3 phase, when the first clock signal CK1 is at a logic high level, the sixth transistor T6 is turned off, and the logic high level corresponding to the input signal IN cannot be transmitted to the third node Q3. At the same time, the first capacitor C1 stabilizes a voltage to the potential of the previous phase so that the potential of the third node Q3 is still maintained at a logic low level, and the second transistor T2 remains turned on. Electric energy stored in the first capacitor C1 may be discharged to the first node Q1 via the second transistor T2 to pull down the potential of the first node Q1. In this case, the fourth transistor T4 continues to be turned on, and the logic low-level signal VGL corresponding to the first terminal of the fourth transistor T4 may be transmitted to the second terminal of the fourth transistor T4, that is, the output signal OUT output by the shift register is still correspondingly at a logic low level. In addition, the input signal IN is at a logic high level. In this case, the seventh transistor T7 is turned off, and the logic high-level signal VGH corresponding to the first terminal of the seventh transistor T7 cannot be transmitted to the fifth node Q5. The fourth capacitor C4 may be charged according to the first clock signal CK1 and discharge to the fifth node Q5. However, since the fourth capacitor C4 stabilizes the voltage to the potential of the previous phase, the tenth transistor T10 remains turned off no matter whether the first clock signal CK1 is at a logic high level or a logic low level. In addition, the eighth transistor T8 is constantly turned on, and the potentials of the third node Q3 and the first node Q1 are both maintained at a logic low level. In this case, the ninth transistor T9 is turned on, and the logic high-level signal VGH corresponding to the first terminal of the ninth transistor T9 may be transmitted to the second node Q2. At the same time, the third capacitor C3 stabilizes the voltage to the potential of the previous phase so that the potential of the second node Q2 is still maintained at a logic high level. In this case, the fifth transistor T5 is turned off.

In an s4 phase, when the first clock signal CK1 is at a logic low level, the sixth transistor T6 is turned on, and a logic high level corresponding to the input signal IN may be transmitted to the third node Q3. The fifth transistor T5 is constantly turned on so that the potentials of the third node Q3 and the first node Q1 are both at a logic high level. In this case, the sixth transistor T6 is turned off. In addition, the input signal IN is at a logic high level. In this case, the seventh transistor T7 is turned off, and the logic high-level signal VGH corresponding to the first terminal of the seventh transistor T7 cannot be transmitted to the fifth node Q5. However, at this time, the fourth capacitor C4 stabilizes the voltage to the potential of the previous phase, that is, the potential of the first clock signal CK1. Therefore, the potential of the fifth node Q5 is at a logic low level corresponding to the first clock signal CK1. In this case, the tenth transistor T10 is turned on. The logic low level corresponding to the first clock signal CK1 may be transmitted to the second node Q2. In this case, the fifth transistor T5 is turned on, and the logic high-level signal VGH corresponding to the first terminal of the fifth transistor T5 may be transmitted to the second terminal of the fifth transistor T5, that is, the output signal OUT output by the shift register is correspondingly at a logic high level. In the s4 phase, when the first clock signal CK1 is at a logic high level, the sixth transistor T6 is turned off, and the logic high level corresponding to the input signal IN cannot be transmitted to the third node Q3. At the same time, the second capacitor C2 stabilizes the voltage to the potential of the previous phase so that the potential of the first node Q1 is still maintained at a logic low level. In this case, the sixth transistor T6 continues to be turned off. In addition, the input signal IN is at a logic high level. In this case, the seventh transistor T7 is turned off, and the logic high-level signal VGH corresponding to the first terminal of the seventh transistor T7 cannot be transmitted to the fifth node Q5. However, at this time, the first capacitor C1 still stabilizes the voltage to the potential of the previous phase, that is, the potential of the first clock signal CK1. Therefore, the potential of the fifth node Q5 is at a logic high level corresponding to the first clock signal CK1. In this case, the tenth transistor T10 is turned off. In addition, at this time, the third capacitor C3 stabilizes the voltage to the potential of the previous phase. The third capacitor C3 discharges to the second node Q2 to maintain the potential of the second node Q2 so that the potential of the second node Q2 is still maintained at a logic low level. In this case, the fifth transistor T5 continues to be turned on, and the logic high-level signal VGH corresponding to the first terminal of the fifth transistor T5 may be transmitted to the second terminal of the fifth transistor T5, that is, the output signal OUT output by the shift register is correspondingly at a logic high level.

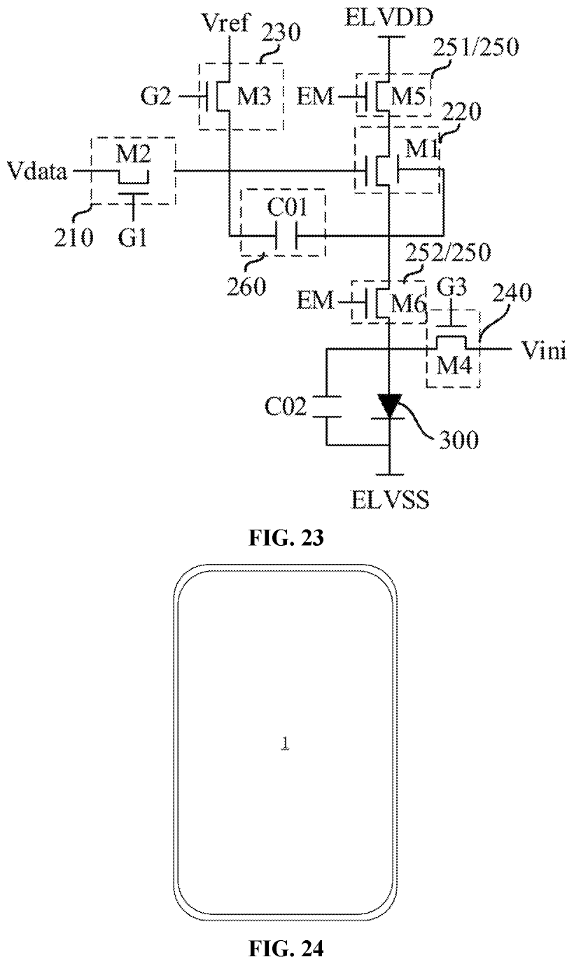

Optionally, FIG. 23 is a schematic diagram illustrating a structure of a pixel circuit in the display panel shown in FIG. 2. As shown in FIG. 2 and FIG. 23, the display panel also includes a pixel circuit 200, and an output signal OUT of the driver circuit 100 is a control signal of a preset unit in the pixel circuit 200. The preset unit is configured to be turned on when the output signal OUT is an active-level signal. The preset unit is configured to be turned off when the output signal OUT is an inactive-level signal.

Optionally, the preset unit includes a P-channel transistor, and the output signal OUT is a control signal of the P-channel transistor. The P-channel transistor is configured to be turned on when the output signal OUT is a logic low-level signal VGL. Alternatively, the preset unit includes an N-channel transistor, and the output signal OUT is a control signal of the N-channel transistor. The N-channel transistor is configured to be turned on when the output signal OUT is a logic high-level signal VGH.

Specifically, when the preset unit includes a P-channel transistor, the active-level signal of the output signal OUT is a logic low-level signal VGL, and when the output signal OUT is a logic low-level signal VGL, the P-channel transistor may be correspondingly controlled to be turned on. In addition, when the preset unit includes an N-channel transistor, the active-level signal of the output signal OUT is a logic high-level signal VGH, and when the output signal OUT is a logic high-level signal VGH, the N-channel transistor may be correspondingly controlled to be turned on. It can be understood that the preset unit may include only a P-channel transistor, may include only an N-channel transistor, or may include both a P-channel transistor and an N-channel transistor. This embodiment is only an example and is not limited. The pixel circuit 200 in the display panel may also have other structures and is not limited to the schematic structural diagram shown in FIG. 23. Those skilled in the art may make reasonable selections and settings according to actual needs.

Optionally, with continued reference to FIG. 2 and FIG. 23, the pixel circuit 200 includes a data writing unit 210, a drive unit 220, a gate reset unit 230, an initialization unit 240, a light emission control unit 250, and an energy storage unit 260. The light emission control unit 250 includes a first light emission control sub-unit 251 and a second light emission control sub-unit 252. The drive unit 220 includes a drive transistor M1, and the drive transistor M1 is configured to provide a drive current for a light-emitting element 300. A first terminal of the data writing unit 210 receives a data signal Vdata, a second terminal of the data writing unit 210 is connected to a gate of the drive transistor M1, and a control terminal of the data writing unit 210 receives a data writing control signal G1. A first terminal of the gate reset unit 230 receives a gate reset signal Vref, a second terminal of the gate reset unit 230 is connected to the gate of the drive transistor M1, and a control terminal of the gate reset unit 230 receives a gate reset control signal G2. A first terminal of the initialization unit 240 receives an initialization signal Vini, a second terminal of the initialization unit 240 is connected to an anode of the light-emitting element 300, and a control terminal of the initialization unit 240 receives an initialization control signal G3. A first terminal of the first light emission control sub-unit 251 receives a first power supply voltage signal ELVDD, a second terminal of the first light emission control sub-unit 251 is connected to a first electrode of the drive transistor M1, and a control terminal of the first light emission control sub-unit 251 receives a light emission control signal EM. A first terminal of the second light emission control sub-unit 252 is connected to a second electrode of the drive transistor M1, a second terminal of the second light emission control sub-unit 252 is connected to the anode of the light-emitting element 300, and a control terminal of the second light emission control sub-unit 252 receives the light emission control signal EM. A first terminal of the energy storage unit 260 is connected to the gate of the drive transistor M1, and a second terminal of the energy storage unit 260 is connected to the second electrode of the drive transistor M1. A cathode of the light-emitting element 300 receives a second power supply voltage signal ELVSS. The preset unit includes at least one of the data writing unit 210, the gate reset unit 230, the initialization unit 240, the first light emission control sub-unit 251, or the second light emission control sub-unit 252.

Specifically, with reference to the pixel circuit 200 shown in FIG. 23, a process in which the driver circuit 100 drives a preset unit is introduced below. First, it is known to those skilled in the art that the pixel circuit 200 shown in FIG. 23 may include the data writing unit 210, the drive unit 220, the gate reset unit 230, the initialization unit 240, the light emission control unit 250, and the energy storage unit 260. The drive unit 220 includes the drive transistor M1, and the drive transistor M1 is configured to provide a drive current for the light-emitting element 300 of the display panel. The first terminal of the data writing unit 210 receives the data signal Vdata, the second terminal of the data writing unit 210 is connected to the gate of the drive transistor M1, and the control terminal of the data writing unit 210 receives the data writing control signal G1. That is, the data writing unit 210 may be turned on or turned off under the action of the potential of the data writing control signal G1. In other words, the data writing control signal G1 controls the turn-on and turn-off of the data writing unit 210. The data writing unit 210 is configured to provide the data signal Vdata for the drive transistor M1. The first terminal of the gate reset unit 230 receives the gate reset signal Vref, the second terminal of the gate reset unit 230 is connected to the gate of the drive transistor M1, and the control terminal of the gate reset unit 230 receives the gate reset control signal G2. That is, the gate reset unit 230 may be turned on or turned off under the action of the potential of the gate reset control signal G2. The gate reset control signal G2 controls the turn-on and turn-off of the gate reset unit 230. The gate reset unit 230 is configured to provide the gate reset signal Vref for the gate of the drive transistor M1. The first terminal of the initialization unit 240 receives the initialization signal Vini, the second terminal of the initialization unit 240 is connected to the anode of the light-emitting element 300, and the control terminal of the initialization unit 240 receives the initialization control signal G3. That is, the initialization unit 240 may be turned on or turned off under the action of the potential of the initialization control signal G3. The initialization control signal G3 controls the turn-on and turn-off of the initialization unit 240. The initialization unit 240 is configured to provide the initialization signal Vini for the anode of the light-emitting element 300. The first terminal of the energy storage unit 260 is connected to the gate of the drive transistor M1, and the second terminal of the energy storage unit 260 is connected to the second electrode of the drive transistor M1. The energy storage unit 260 is configured to store a signal transmitted to the gate of the drive transistor M1.

The light emission control unit 250 is configured to selectively allow the light-emitting element 300 to enter a light emission phase. Optionally, the light emission control unit 250 includes a first light emission control sub-unit 251 and a second light emission control sub-unit 252. The first light emission control sub-unit 251 is connected between the first power supply voltage signal ELVDD and the first electrode of the drive transistor M1. The second light emission control sub-unit 252 is connected between the second electrode of the drive transistor M1 and the anode of the light-emitting element 300. The cathode of the light-emitting element 300 receives the second power supply voltage signal ELVSS. In addition, the control terminal of the first light emission control sub-unit 251 receives the light emission control signal EM, and the control terminal of the second light emission control sub-unit 252 receives the light emission control signal EM. That is, the first light emission control sub-unit 251 may be turned on or turned off under the action of the potential of the light emission control signal EM, and the second light emission control sub-unit 252 may also be turned on or turned off under the action of the potential of the light emission control signal EM. In other words, the light emission control signal EM controls the turn-on and turn-off of the first light emission control sub-unit 251 and the second light emission control sub-unit 252. Illustratively, the turn-on of the first light emission control sub-unit 251 and the second light emission control sub-unit 252 may cause the corresponding light-emitting element 300 to enter a light emission phase. More specifically, in this embodiment, the pixel circuit 200 receives the first power supply voltage signal ELVDD and the second power supply voltage signal ELVSS. A drive current is controlled through a potential difference between the first power supply voltage signal ELVDD and the second power supply voltage signal ELVSS and through the data signal Vdata written to the gate of the drive transistor M1, thereby driving the light-emitting element 300 to emit light. Illustratively, the first power supply voltage signal ELVDD may be a positive power supply signal, and the second power supply voltage signal ELVSS may be a negative power supply signal.

In addition, illustratively, the pixel circuit 200 may also include a compensation unit. The compensation unit may be connected between the gate of the drive transistor M1 and the second electrode of the drive transistor M1. The compensation unit is configured to compensate a threshold voltage of the drive transistor M1. Illustratively, the pixel circuit 200 may also include a bias adjustment unit. The bias adjustment unit is connected to the first electrode of the drive transistor M1, or the bias adjustment unit is connected to the second electrode of the drive transistor M1. The bias adjustment unit is configured to provide a bias adjustment signal for the drive transistor M1. Illustratively, a control terminal of the bias adjustment unit receives a bias adjustment control signal, and the bias adjustment control signal controls the turn-on and turn-off of the bias adjustment unit.

Based on the preceding pixel circuit 200, the driver circuit 100 in the embodiments of the present disclosure may correspondingly provide control signals to the data writing unit 210, the gate reset unit 230, the initialization unit 240, the first light emission control sub-unit 251, and the second light emission control sub-unit 252. That is, the preset unit of the pixel circuit 200 described above may be any one of the data writing unit 210, the gate reset unit 230, the initialization unit 240, the first light emission control sub-unit 251, and the second light emission control sub-unit 252. The output signal OUT of the driver circuit 100 may be a control signal of at least one of the preceding units. The driving principle of the pixel circuit 200 is introduced below with an example in which the output signal OUT of the driver circuit 100 serves as a control signal of the data writing unit 210.

With continued reference to FIG. 2 to FIG. 6, generally, shift registers 110 of different stages provide drive signals to pixel circuits 200 of different rows, that is, provide a data writing control signal G1 to the data writing unit 210 in the pixel circuits 200 of different rows. An i-th stage shift register 110 is used as an example. During at least part of a period in which the potential of the second node Q2 is an inactive-level signal, the potential of the first node Q1 is maintained at the active-level signal for the first output sub-unit 21 to ensure that the output signal OUT outputs an active-level signal, that is, the output signal OUT outputs an active pulse. In this case, the data writing unit 210 is turned on, the pixel circuit 200 starts to write the data signal, and a storage capacitor C0 in the energy storage unit 260 starts to be charged. In addition, since the output signal OUT outputs a complete active pulse, the storage capacitor C0 may be fully charged so that the light-emitting element 300 may emit light normally according to requirements in a light emission phase. Another stage of shift register 110 is used as an example. The output signal OUT does not output an active pulse. In this case, the data writing unit 210 is turned off, the pixel circuit 200 cannot write the data signal, and a storage capacitor C01 in the energy storage unit 260 starts to discharge. It can thus be known that the shift register 110 can control whether the light-emitting elements 300 of different rows emit light. A storage capacitor C02 may also be disposed between the anode and the cathode of the light-emitting element 300.

Those skilled in the art may know that, for other units in the pixel circuit 200, the turn-on process of each unit in each data refresh cycle directly affects whether the pixel circuit 200 may drive a corresponding light-emitting element 300 to emit light. In other words, when the output signal OUT serves as a control signal for other units except the data writing unit 210, the shift register 110 may control whether the corresponding light-emitting element 300 emits light normally. Those skilled in the art may deduce this according to the implementation manner of the specific function of each unit, and details are not repeated herein. It is to be additionally noted that the preset unit in the pixel circuit 200 refers specifically to a unit whose control signal is directly input externally, such as the data writing unit 210, the gate reset unit 230, the initialization unit 240, the first light emission control sub-unit 251, and the second light emission control sub-unit 252. For the drive unit 220 that is turned on or turned off under the control of the input data signal, the drive unit 220 is not directly controlled by an external signal. Therefore, the output signal OUT of the driver circuit 100 in the present disclosure cannot serve as a control signal of the preset unit of the pixel circuit 200.

Optionally, with continued reference to FIG. 23, the data writing unit 210, the gate reset unit 230, the initialization unit 240, the first light emission control sub-unit 251, and the second light emission control sub-unit 252 each include a P-channel transistor or an N-channel transistor.

Illustratively, the drive unit 220 includes the drive transistor M1. The data writing unit 210 includes a data writing transistor M2, and the data writing control signal G1 may control the turn-on and turn-off of the data writing transistor M2. The gate reset unit 230 includes a gate reset transistor M3, and the gate reset control signal G2 controls the turn-on and turn-off of the gate reset transistor M3. The initialization unit 240 includes an initialization transistor M4, and the initialization control signal G3 controls the turn-on and turn-off of the initialization transistor M4. The first light emission control sub-unit 251 includes a first light emission control transistor M5, and the light emission control signal EM controls the turn-on and turn-off of the first light emission control transistor M5. The second light emission control sub-unit 252 includes a second light emission control transistor M6, and the light emission control signal EM controls the turn-on and turn-off of the second light emission control transistor M6. Illustratively, the drive transistor M1, the data writing transistor M2, the gate reset transistor M3, the initialization transistor M4, the first light emission control transistor M5, and the second light emission control transistor M6 may all be N-channel transistors, or may all be P-channel transistors, or part of the drive transistor M1, the data writing transistor M2, the gate reset transistor M3, the initialization transistor M4, the first light emission control transistor M5, and the second light emission control transistor M6 may be N-channel transistors and the remaining transistors may be P-channel transistors. The types of the transistors shown in FIG. 23 are only examples and are not limited.

Based on the same concept, embodiments of the present disclosure also provide a display device. FIG. 24 is a diagram illustrating the structure of a display device according to an embodiment of the present disclosure. As shown in FIG. 24, the display device includes the display panel 1 provided by any embodiment of the present disclosure. Thus, the display device provided by the embodiments of the present disclosure has the corresponding beneficial effects of the display panel provided by the embodiments of the present disclosure, which are not repeated here. Illustratively, the display device may be an electronic device such as a mobile phone, a computer, a smart wearable device (for example, a smart watch), or an in-vehicle display device, which is not limited in the embodiments of the present disclosure.

It is to be understood that various forms of processes shown above may be adopted with steps reordered, added, or deleted. For example, the steps described in the present disclosure may be performed in parallel, sequentially, or in different orders, as long as the desired results of the technical solutions of the present disclosure can be achieved, and no limitation is imposed herein.

The preceding embodiments do not limit the scope of the present disclosure. It is to be understood by those skilled in the art that various modifications, combinations, sub-combinations, and substitutions may be performed according to design requirements and other factors. Any modifications, equivalent substitutions, improvements, and the like made within the spirit and principle of the present disclosure are within the scope of the present disclosure.

What is claimed is:

1. A shift register, comprising:
a control unit, wherein the control unit is configured to receive an input signal and a first clock signal, and to control a potential of a first node and a potential of a second node, wherein one of the potential of the first node and the potential of the second node is a logic high-level signal, and the other of the potential of the first node and the potential of the second node is a logic low-level signal;
an output unit comprising a first output sub-unit and a second output sub-unit, wherein a first terminal of the first output sub-unit receives a first voltage signal, a first terminal of the second output sub-unit receives a second voltage signal, and a second terminal of the first output sub-unit and a second terminal of the second output sub-unit are connected and output an output signal, wherein one of the first voltage signal and the second voltage signal is a logic high-level signal, and the other of the first voltage signal and the second voltage signal is a logic low-level signal;
wherein a control terminal of the first output sub-unit is connected to the first node, and the first output sub-unit is configured to output the first voltage signal when the potential of the first node is an active-level signal; and a control terminal of the second output sub-unit is connected to the second node, and the second output sub-unit is configured to output the second voltage signal when the potential of the second node is an active-level signal; and
a node voltage regulation unit, wherein the node voltage regulation unit is connected to the first node and configured to maintain the potential of the first node at an active-level signal for the first output sub-unit during at least part of a period in which the potential of the second node is an inactive-level signal.

2. The shift register according to claim 1, wherein an active-level signal of the first node is a logic high-level signal, and the potential of the first node satisfies: U1′≤U1″; or, an active-level signal of the first node is a logic low-level signal, and the potential of the first node satisfies: U1′≥U1″;
wherein U1′ denotes the potential of the first node in a phase in which the input signal is an active-level signal and the first clock signal first switches to an active-level signal, and U1″ denotes the potential of the first node in a phase in which the input signal is an active-level signal and the first clock signal is an inactive-level signal, or in a phase in which the input signal switches from an active-level signal to an inactive-level signal and the first clock signal is an inactive-level signal.

3. The shift register according to claim 1, wherein the control unit comprises a third node, and one of a potential of the third node and the potential of the second node is a logic high-level signal, and the other of the potential of the third node and the potential of the second node is a logic low-level signal; and
a control terminal of the node voltage regulation unit is connected to the third node, and the node voltage regulation unit is configured to maintain the potential of the first node at the active-level signal for the first output sub-unit during at least part of a period in which the potential of the third node is an active-level signal.

4. The shift register according to claim 3, wherein an active-level signal of the first node is a logic high-level signal, and in a phase in which the first node is at the active-level signal, U1≥U3; or, an active-level signal of the first node is a logic low-level signal, and in a phase in which the first node is at the active-level signal, U1≤U3;
wherein U1 denotes the potential of the first node, and U3 denotes the potential of the third node.

5. The shift register according to claim 3, wherein the node voltage regulation unit comprises a first switching sub-unit, a second switching sub-unit, and a first energy storage sub-unit;
a first terminal of the first switching sub-unit receives a second clock signal, a second terminal of the first switching sub-unit is connected to a first terminal of the first energy storage sub-unit, a second terminal of the first energy storage sub-unit, a control terminal of the first switching sub-unit, a first terminal of the second switching sub-unit, and a control terminal of the second switching sub-unit are connected to a fourth node, the fourth node is connected to the third node, and a second terminal of the second switching sub-unit is connected to the first node, wherein the second clock signal and the first clock signal are inverted in phase;
the first switching sub-unit and the second switching sub-unit are configured to be turned on when the third node is at an active-level signal; and
the first energy storage sub-unit is configured to receive the second clock signal for charging when the first clock signal is an active-level signal, and the first energy storage sub-unit is configured to discharge to the first node through the turned-on second switching sub-unit when the first clock signal switches from an active-level signal to an inactive-level signal, to maintain the potential of the first node.

6. The shift register according to claim 5, wherein the node voltage regulation unit further comprises a third switching sub-unit connected between the fourth node and the third node; and
a control terminal of the third switching sub-unit receives the first voltage signal; or, a control terminal of the third switching sub-unit receives the first clock signal.

7. The shift register according to claim 6, wherein the third switching sub-unit comprises a third transistor; and
the third transistor is connected between the fourth node and the third node, and a gate of the third transistor receives the first voltage signal or the first clock signal.

8. The shift register according to claim 1, wherein a control terminal of the node voltage regulation unit receives the input signal, and the node voltage regulation unit is configured to maintain the potential of the first node at the active-level signal for the first output sub-unit at least during a period in which a potential of the input signal is an active-level signal and the first clock signal is an inactive-level signal.

9. The shift register according to claim 8, wherein the node voltage regulation unit comprises a first switching sub-unit, a second switching sub-unit, a third switching sub-unit, and a first energy storage sub-unit;
a first terminal of the first switching sub-unit receives a second clock signal, a second terminal of the first switching sub-unit is connected to a first terminal of the first energy storage sub-unit, a second terminal of the first energy storage sub-unit, a control terminal of the first switching sub-unit, a first terminal of the second switching sub-unit, and a control terminal of the second switching sub-unit are connected to a fourth node, and a second terminal of the second switching sub-unit is connected to the first node, wherein the second clock signal and the first clock signal are inverted in phase;
a first terminal of the third switching sub-unit is connected to the fourth node, a second terminal of the third switching sub-unit receives the input signal, and a control terminal of the third switching sub-unit receives the first clock signal;
the third switching sub-unit is configured to be turned on when the first clock signal is an active-level signal, and the first switching sub-unit and the second switching sub-unit are configured to be turned on when the input signal is an active-level signal; and
the first energy storage sub-unit is configured to receive the second clock signal and the input signal at two terminals of the first energy storage sub-unit for charging when the first clock signal is an active-level signal, and the first energy storage sub-unit is configured to discharge to the first node through the turned-on second switching sub-unit when the first clock signal is an inactive-level signal, to maintain the potential of the first node.

10. The shift register according to claim 6, wherein the first switching sub-unit comprises a first transistor, the second switching sub-unit comprises a second transistor, the third switching sub-unit comprises a third transistor, and the first energy storage sub-unit comprises a first capacitor;
a first electrode of the first transistor receives the second clock signal, a second electrode of the first transistor is connected to a first plate of the first capacitor, a second plate of the first capacitor, a gate of the first transistor, a gate of the second transistor, and a first electrode of the second transistor are all connected to the fourth node;
a second electrode of the second transistor is connected to the first node, a first electrode of the third transistor is connected to the fourth node, a second electrode of the third transistor receives the input signal, and a gate of the third transistor receives the first clock signal; and
the first transistor, the second transistor, and the third transistor have a same channel type.

11. The shift register according to claim 10, wherein the first transistor, the second transistor, and the third transistor are all P-channel transistors or all N-channel transistors.

12. The shift register according to claim 1, wherein the first output sub-unit comprises a fourth switching sub-unit and a second energy storage sub-unit, and the second output sub-unit comprises a fifth switching sub-unit and a third energy storage sub-unit;
a first terminal of the fourth switching sub-unit receives the first voltage signal, and a control terminal of the fourth switching sub-unit and a first terminal of the second energy storage sub-unit are both connected to the first node;
a first terminal of the fifth switching sub-unit receives the second voltage signal, and a control terminal of the fifth switching sub-unit and a first terminal of the third energy storage sub-unit are both connected to the second node;
a second terminal of the fourth switching sub-unit, a second terminal of the second energy storage sub-unit, a second terminal of the fifth switching sub-unit, and a second terminal of the third energy storage sub-unit are connected to each other and output the output signal;
the fourth switching sub-unit is configured to be turned on when the first node is at an active-level signal;
the second energy storage sub-unit is configured to charge at least when the first clock signal is an active-level signal, and to discharge to the first node when the first clock signal switches from an active-level signal to an inactive-level signal, to maintain the potential of the first node;
the fifth switching sub-unit is configured to be turned on when the second node is at an active-level signal; and
the third energy storage sub-unit is configured to charge at least when the first clock signal is an active-level signal, and the third energy storage sub-unit is configured to discharge to the second node when the first clock signal switches from an inactive-level signal to an active-level signal, to maintain the potential of the second node.

13. The shift register according to claim 12, wherein the fourth switching sub-unit comprises a fourth transistor, the second energy storage sub-unit comprises a second capacitor, the fifth switching sub-unit comprises a fifth transistor, the third energy storage sub-unit comprises a third capacitor, and the fourth transistor and the fifth transistor have a same channel type;
a first electrode of the fourth transistor receives the first voltage signal, and a gate of the fourth transistor and a first plate of the second capacitor are both connected to the first node;
a first electrode of the fifth transistor receives the second voltage signal, and a gate of the fifth transistor and a first plate of the third capacitor are both connected to the second node; and
a second electrode of the fourth transistor, a second plate of the second capacitor, a second electrode of the fifth transistor, and a second plate of the third capacitor are connected to each other and output the output signal.

14. The shift register according to claim 13, wherein the fourth transistor and the fifth transistor are both N-channel transistors, the first voltage signal is a logic high-level signal, and the second voltage signal is a logic low-level signal; or,
the fourth transistor and the fifth transistor are both P-channel transistors, the first voltage signal is a logic low-level signal, and the second voltage signal is a logic high-level signal.

15. The shift register according to claim 1, wherein the control unit comprises a sixth switching sub-unit, a seventh switching sub-unit, an eighth switching sub-unit, a ninth switching sub-unit, a tenth switching sub-unit, and a fourth energy storage sub-unit;
a first terminal of the sixth switching sub-unit and a control terminal of the seventh switching sub-unit are connected and receive the input signal, a second terminal of the sixth switching sub-unit, a first terminal of the eighth switching sub-unit, and a control terminal of the ninth switching sub-unit are connected to a third node, and a control terminal of the sixth switching sub-unit receives the first clock signal;
a first terminal of the seventh switching sub-unit receives the second voltage signal, a second terminal of the seventh switching sub-unit, a control terminal of the tenth switching sub-unit, and a first terminal of the fourth energy storage sub-unit are connected to a fifth node;
a second terminal of the eighth switching sub-unit is connected to the first node, and a control terminal of the eighth switching sub-unit receives the first voltage signal;
a first terminal of the ninth switching sub-unit receives the second voltage signal, and a second terminal of the ninth switching sub-unit and a first terminal of the tenth switching sub-unit are connected to the second node;
a second terminal of the tenth switching sub-unit is connected to a second terminal of the fourth energy storage sub-unit;
the sixth switching sub-unit is configured to be turned on when the first clock signal is an active-level signal;
the seventh switching sub-unit is configured to be turned on when the input signal is an active-level signal; and
the fourth energy storage sub-unit is configured to receive the second voltage signal for charging when the input signal is an active-level signal, and to discharge to the fifth node when the input signal switches from an active-level signal to an inactive-level signal, to maintain a potential of the fifth node.

16. The shift register according to claim 15, wherein the sixth switching sub-unit comprises a sixth transistor, the seventh switching sub-unit comprises a seventh transistor, the eighth switching sub-unit comprises an eighth transistor, the ninth switching sub-unit comprises a ninth transistor, the tenth switching sub-unit comprises a tenth transistor, the fourth energy storage sub-unit comprises a fourth capacitor, and the sixth transistor, the seventh transistor, the eighth transistor, the ninth transistor, and the tenth transistor have a same channel type;
a first electrode of the sixth transistor and a gate of the seventh transistor are connected and receive the input signal, a second electrode of the sixth transistor, a first electrode of the eighth transistor, and a gate of the ninth transistor are connected to the third node, and a gate of the sixth transistor receives the first clock signal;
a first electrode of the seventh transistor receives the second voltage signal, and a second electrode of the seventh transistor, a gate of the tenth transistor, and a first plate of the fourth capacitor are connected to the fifth node;
a second electrode of the eighth transistor is connected to the first node, and a gate of the eighth transistor receives the first voltage signal;
a first electrode of the ninth transistor receives the second voltage signal, and a second electrode of the ninth transistor and a first electrode of the tenth transistor are connected to the second node; and
a second electrode of the tenth transistor is connected to a second plate of the fourth capacitor.

17. The shift register according to claim 16, wherein the sixth transistor, the seventh transistor, the eighth transistor, the ninth transistor, and the tenth transistor are all P-channel transistors or all N-channel transistors.

18. The shift register according to claim 16, wherein the sixth switching sub-unit further comprises an eleventh transistor, and the eleventh transistor has a same channel type as the sixth transistor; and
a first electrode of the eleventh transistor is connected to the second electrode of the sixth transistor, a second electrode of the eleventh transistor is connected to the third node, and a gate of the eleventh transistor receives the first clock signal.

19. The shift register according to claim 18, wherein the sixth switching sub-unit further comprises a twelfth transistor, and the twelfth transistor has a same channel type as the sixth transistor;
the second electrode of the sixth transistor and the first electrode of the eleventh transistor are connected to a sixth node, and a first electrode of the twelfth transistor is connected to the sixth node; and
a second electrode of the twelfth transistor receives the first voltage signal, and a gate of the twelfth transistor is connected to the third node; or, a second electrode of the twelfth transistor receives a third voltage signal, and a gate of the twelfth transistor is connected to the first node;
wherein the first voltage signal is a logic high-level signal, and the third voltage signal is greater than the first voltage signal; or the first voltage signal is a logic low-level signal, and the third voltage signal is smaller than the first voltage signal.

20. A display panel, comprising a driver circuit, wherein the driver circuit comprises N stages of shift registers cascaded in sequence, each of the shift registers comprises:
a control unit, wherein the control unit is configured to receive an input signal and a first clock signal, and to control a potential of a first node and a potential of a second node, wherein one of the potential of the first node and the potential of the second node is a logic high-level signal, and the other of the potential of the first node and the potential of the second node is a logic low-level signal;
an output unit comprising a first output sub-unit and a second output sub-unit, wherein a first terminal of the first output sub-unit receives a first voltage signal, a first terminal of the second output sub-unit receives a second voltage signal, and a second terminal of the first output sub-unit and a second terminal of the second output sub-unit are connected and output an output signal, wherein one of the first voltage signal and the second voltage signal is a logic high-level signal, and the other of the first voltage signal and the second voltage signal is a logic low-level signal;
wherein a control terminal of the first output sub-unit is connected to the first node, and the first output sub-unit is configured to output the first voltage signal when the potential of the first node is an active-level signal; and a control terminal of the second output sub-unit is connected to the second node, and the second output sub-unit is configured to output the second voltage signal when the potential of the second node is an active-level signal;
a node voltage regulation unit, wherein the node voltage regulation unit is connected to the first node and configured to maintain the potential of the first node at an active-level signal for the first output sub-unit during at least part of a period in which the potential of the second node is an inactive-level signal; and
an output signal of an i-th stage shift register is input into a j-th stage shift register as an input signal of the j-th stage shift register, wherein N≥2, 1≤i≤N, and 1≤j≤N.

21. The display panel according to claim 20, further comprising a pixel circuit, wherein an output signal of the driver circuit is a control signal of a preset unit in the pixel circuit;
the preset unit is configured to be turned on when the output signal is an active-level signal; and
the preset unit is configured to be turned off when the output signal is an inactive-level signal.

22. The display panel according to claim 21, wherein the preset unit comprises a P-channel transistor, and the output signal is a control signal of the P-channel transistor, wherein the P-channel transistor is configured to be turned on when the output signal is a logic low-level signal; or,
the preset unit comprises an N-channel transistor, and the output signal is a control signal of the N-channel transistor, wherein the N-channel transistor is configured to be turned on when the output signal is a logic high-level signal.

23. The display panel according to claim 22, wherein the pixel circuit comprises a drive unit, a data writing unit, a gate reset unit, an initialization unit, a light emission control unit, and an energy storage unit;
the light emission control unit comprises a first light emission control sub-unit and a second light emission control sub-unit;
the drive unit comprises a drive transistor configured to provide a drive current for a light-emitting element;
a first terminal of the data writing unit receives a data signal, a second terminal of the data writing unit is connected to a gate of the drive transistor, and a control terminal of the data writing unit receives a data writing control signal;
a first terminal of the gate reset unit receives a gate reset signal, a second terminal of the gate reset unit is connected to the gate of the drive transistor, and a control terminal of the gate reset unit receives a gate reset control signal;
a first terminal of the initialization unit receives an initialization signal, a second terminal of the initialization unit is connected to an anode of the light-emitting element, and a control terminal of the initialization unit receives an initialization control signal;
a first terminal of the first light emission control sub-unit receives a first power supply voltage signal, a second terminal of the first light emission control sub-unit is connected to a first electrode of the drive transistor, and a control terminal of the first light emission control sub-unit receives a light emission control signal;
a first terminal of the second light emission control sub-unit is connected to a second electrode of the drive transistor, a second terminal of the second light emission control sub-unit is connected to the anode of the light-emitting element, and a control terminal of the second light emission control sub-unit receives the light emission control signal;
a first terminal of the energy storage unit is connected to the gate of the drive transistor, and a second terminal of the energy storage unit is connected to the second electrode of the drive transistor;
a cathode of the light-emitting element receives a second power supply voltage signal; and
the preset unit comprises at least one of the data writing unit, the gate reset unit, the initialization unit, the first light emission control sub-unit, or the second light emission control sub-unit.

24. The display panel according to claim 23, wherein the data writing unit, the gate reset unit, the initialization unit, the first light emission control sub-unit, and the second light emission control sub-unit each comprise a P-channel transistor or an N-channel transistor.
